(19) United States
(12) Patent Application Publication
(10) Pub. No.: US 2013/0240873 A1
(43) Pub. Date: Sep. 19, 2013

(54) SEMICONDUCTOR DEVICE

(71) Applicant: SEMICONDUCTOR ENERGY LABORATORY CO., LTD., Atsugi-shi (JP)

(72) Inventors: Shunpei YAMAZAKI, Setagaya (JP); Jun KOYAMA, Sagamihara (JP)

(73) Assignee: SEMICONDUCTOR ENERGY LABORATORY CO., LTD., Atsugi-shi (JP)

(21) Appl. No.: 13/790,391

(22) Filed: Mar. 8, 2013

(30) Foreign Application Priority Data
Mar. 14, 2012 (JP) 2012-057974

(51) Int. Cl. H01L 29/786

(52) U.S. Cl. CPC H01L 29/78609
USPC 257/43

(57) ABSTRACT

To provide a semiconductor device with low power consumption in which a malfunction due to drop in voltage, delay of signal transmission, distortion of a signal waveform, and the like, which are caused by increase in wiring resistance, and decrease in reliability are prevented. A gate wiring is formed of a conductive layer containing copper, and a signal wiring formed of part of the same conductive layer as a source electrode and a drain electrode and a wiring formed of part of the same conductive layer as the gate wiring are electrically connected to each other in series or in parallel; thus, wiring resistance of the signal wiring is substantially decreased without an increase in width or thickness of the signal wiring.

### BACKGROUND OF THE INVENTION

1. Field of the Invention

The present invention relates to a semiconductor device and a manufacturing method thereof.

In this specification and the like, the semiconductor device refers to any device which can function by utilizing semiconductor characteristics; an electro-optical device, a display device, a semiconductor circuit, and an electronic device are all included in the category of the semiconductor device.

2. Description of the Related Art

A technique by which a transistor (also referred to as a thin film transistor (TFT)) is formed using a semiconductor thin film formed over a substrate having an insulating surface has been attracting attention. The transistor has been applied to a wide range of electronic devices such as an integrated circuit (IC) and an image display device (display device). A silicon-based semiconductor material is widely known as a material for a semiconductor thin film applicable to a transistor. In recent years, with an increase in integration of a semiconductor circuit or definition of a display device, an oxide semiconductor material has been attracting attention as a material having higher performance than a silicon-based semiconductor material.

For example, a transistor whose active layer includes an amorphous oxide including indium (In), gallium (Ga), and zinc (Zn) is disclosed (see Patent Document 1).

In particular, in an active matrix semiconductor device typified by a liquid crystal display device and an EL (electro luminescence) display device, a trend in resolution of a screen is toward higher definition, e.g., high-definition (HD) quality (1366×768) or full high-definition (FHD) quality (1920×1080), and prompt development of a 4K Digital Cinema display device, which has a resolution of 3840×2048 or 4096×2180, is also demanded. In addition, there is a trend toward a larger screen.

Increase in definition or screen size tends to increase wiring resistance in a display portion. Increase in wiring resistance causes drop in voltage of a power supply line, delay of signal transmission to an end portion of a signal line, distortion of a signal waveform, or the like. As a result, deterioration of display quality, such as display unevenness or a defect in grayscale, or increase in power consumption is caused. In addition, also in semiconductor devices other than display devices, increase in wiring resistance causes drop in voltage of a power supply line, delay of signal transmission, distortion of a signal waveform, or the like, resulting in a malfunction, decrease in reliability, or increase in power consumption.

In order to suppress increase in wiring resistance, a technique of forming a low-resistance wiring layer with the use of copper (Cu) is considered (e.g., see Patent Documents 2 and 3).

### REFERENCE

### Patent Document

[Patent Document 1] Japanese Published Patent Application No. 2006-165528
[Patent Document 2] Japanese Published Patent Application No. 2004-133422
[Patent Document 3] Japanese Published Patent Application No. 2004-163901

### SUMMARY OF THE INVENTION

However, since Cu easily diffuses into a semiconductor or silicon oxide, the operation of a semiconductor device might be unstable and yield might be significantly reduced. In particular, an oxide semiconductor is likely to be affected by Cu as compared to a silicon-based semiconductor, and deterioration in electric characteristics of a transistor or decrease in reliability easily occurs by Cu diffusion.

When the width of a wiring is increased to reduce wiring resistance, an area occupied by the wiring is increased; thus, it is difficult to achieve higher definition. Further, when the thickness of a wiring is increased to reduce wiring resistance, film formation time is increased and coverage with a layer to be formed over the wiring easily becomes poor, which leads to reduction in productivity.

An object of one embodiment of the present invention is to provide a transistor having favorable electric characteristics and high reliability and a semiconductor device including the transistor.

Another object of one embodiment of the present invention is to provide a display device with higher display quality in which a defect in signal writing, a defect in grayscale due to distortion of a signal waveform, and the like are prevented.

Another object of one embodiment of the present invention is to provide a semiconductor device with low power consumption in which a malfunction due to drop in voltage, delay of signal transmission, distortion of a signal waveform, and the like which are caused by increase in wiring resistance, and decrease in reliability are prevented.

With use of a conductive layer containing copper as a gate wiring, wiring resistance of the gate wiring is reduced. Further, when a source electrode and a drain electrode which are in contact with an oxide semiconductor layer are formed without using copper, deterioration of electric characteristics of a transistor and a decrease in reliability which are caused by diffusion of copper are prevented.

A signal wiring formed using part of the same conductive layer as the source electrode and the drain electrode is electrically connected to a wiring formed using part of the same conductive layer as the gate wiring in series or in parallel; thus, wiring resistance of the signal wiring can be substantially reduced without an increase in the width or the thickness of the signal wiring.

When the wiring containing copper is covered with an insulating layer having barrier properties, diffusion of copper can be suppressed. For the insulating layer having barrier properties, for example, silicon nitride, aluminum oxide, or the like can be used.

One embodiment of the present invention is a semiconductor device including a first wiring formed of a conductive layer containing copper, a second wiring formed of part of a conductive layer in contact with an oxide semiconductor layer, and an insulating layer, in which the insulating layer is over the first wiring, the second wiring is over the insulating layer, and the first wiring and the second wiring are electrically connected to each other in parallel through a contact hole in the insulating layer. Further, the first wiring and the second wiring may overlap with each other.

One embodiment of the present invention is a semiconductor device including a plurality of first wirings formed of a conductive layer containing copper, a plurality of second wirings formed of part of a conductive layer in contact with an oxide semiconductor layer, and an insulating layer, in which the insulating layer is over the first wiring, the second wiring is over the insulating layer, and the first wiring and the second wiring are electrically connected to each other in series through a contact hole in the insulating layer.

The first wiring and the second wiring may be connected through one contact hole or a plurality of contact holes.

The insulating layer may be a stack of an insulating layer having barrier properties and an insulating layer containing oxygen. For example, a stack of silicon nitride and silicon nitride oxide may be used.

According to one embodiment of the present invention, a transistor having favorable electric characteristics and high reliability and a semiconductor device including the transistor can be provided.

According to one embodiment of the present invention, a semiconductor device typified by a display device having high display quality can be provided.

According to one embodiment of the present invention, a semiconductor device with few malfunctions, favorable reliability, and low power consumption can be provided.

### BRIEF DESCRIPTION OF THE DRAWINGS

In the accompanying drawings:

FIG. 1 is a top view illustrating one embodiment of the present invention;

FIGS. 2A and 2B are cross-sectional views illustrating one embodiment of the present invention;

FIG. 3 is a top view illustrating one embodiment of the present invention;

FIG. 4 is a cross-sectional view illustrating one embodiment of the present invention;

FIGS. 5A to 5C are circuit diagrams illustrating embodiments of the present invention;

FIG. 6 is a top view illustrating one embodiment of the present invention;

FIG. 7 is a top view illustrating one embodiment of the present invention;

FIGS. 8A and 8B are cross-sectional views illustrating one embodiment of the present invention;

FIG. 9 is a cross-sectional view illustrating one embodiment of the present invention;

FIGS. 10A1 and 10A2 and FIGS. 10B1 and 10B2 are top views and cross-sectional views illustrating embodiments of the present invention;

FIGS. 11A1, 11A2, 11B1, 11B2, 11C1, 11C2, 11D1, and 11D2 illustrate a manufacturing method;

FIGS. 12A1, 12A2, 12B1, and 12B2 illustrate a manufacturing method;

FIGS. 13A1, 13A2, 13B1, 13B2, 13C1, and 13C2 illustrate a manufacturing method;

FIGS. 14A to 14D illustrate a manufacturing method;

FIGS. 15A to 15C illustrate a manufacturing method;

FIGS. 16A to 16C illustrate embodiments of the present invention;

FIGS. 17A and 17B illustrate embodiments of the present invention;

FIGS. 18A and 18B illustrate one embodiment of the present invention;

FIGS. 19A and 19B illustrate one embodiment of the present invention; and

FIGS. 20A to 20F illustrate electronic appliances.

### DETAILED DESCRIPTION OF THE INVENTION

Hereinafter, embodiments of the present invention will be described with reference to the drawings. Note that the present invention is not limited to the following description, and it will be readily appreciated by those skilled in the art that the mode and details can be changed in various different ways without departing from the spirit and the scope of the present invention. Therefore, the present invention should not be construed as being limited to the following description of the embodiments. Note that in the structures of the present invention which are described below, the same reference numerals are commonly used to denote the same components or components having similar functions among different drawings, and description of such components is not repeated.

In addition, in this specification and the like, ordinal numbers such as “first”, “second”, and “third” are used in order to avoid confusion among components, and the terms do not limit the components numerically.

In addition, the position, size, range, or the like of each structure illustrated in drawings and the like is not accurately represented in some cases for easy understanding. Therefore, the disclosed invention is not necessarily limited to the position, size, range, or the like as disclosed in the drawings and the like.

A transistor is one kind of semiconductor elements and can amplify current or voltage and perform a switching operation for controlling conduction or non-conduction, for example. A transistor in this specification includes an insulated-gate field effect transistor (IGFET) and a thin film transistor (TFT).

Functions of a “source” and a “drain” of a transistor might interchange when a transistor of opposite polarity is used or the direction of current flow is changed in circuit operation, for example. Therefore, the terms “source” and “drain” can be used to denote the drain and the source, respectively, in this specification.

In addition, in this specification and the like, the term such as “electrode” or “wiring” does not limit a function of a component. For example, an “electrode” is sometimes used as part of a “wiring”, and vice versa. Further, the term “electrode” or “wiring” can also mean a combination of a plurality of “electrodes” and “wirings” formed in a connected manner.

### Embodiment 1

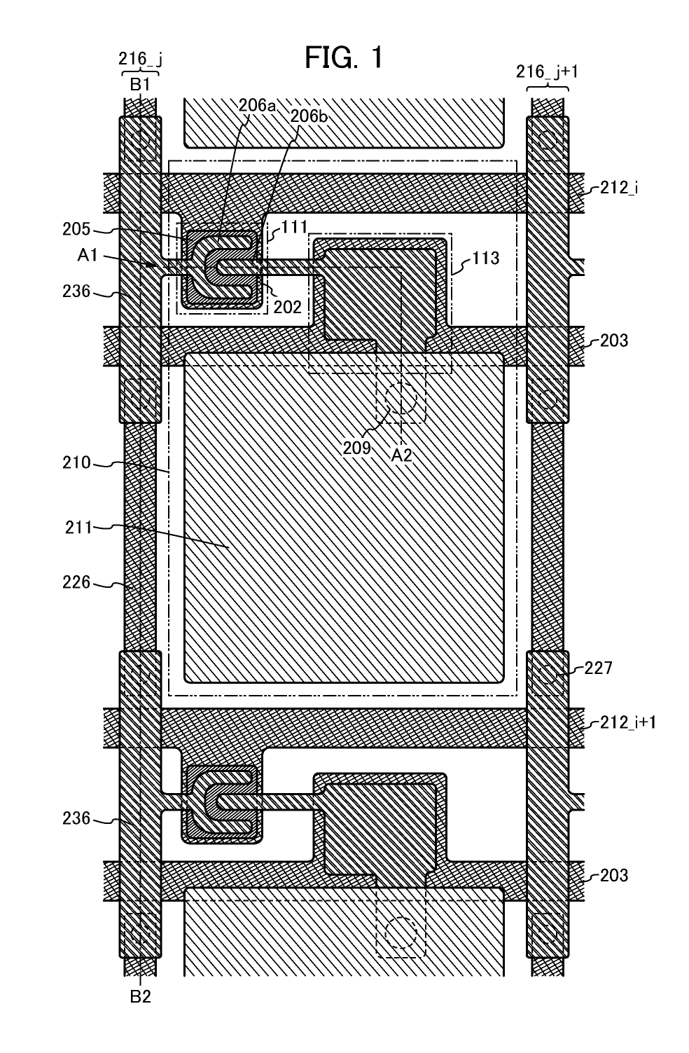

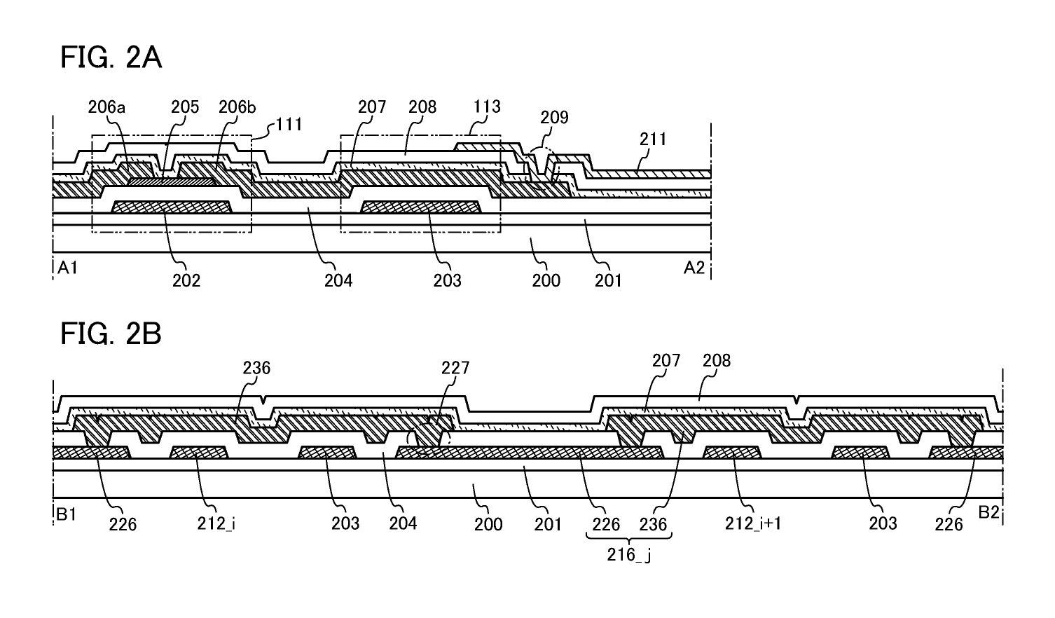

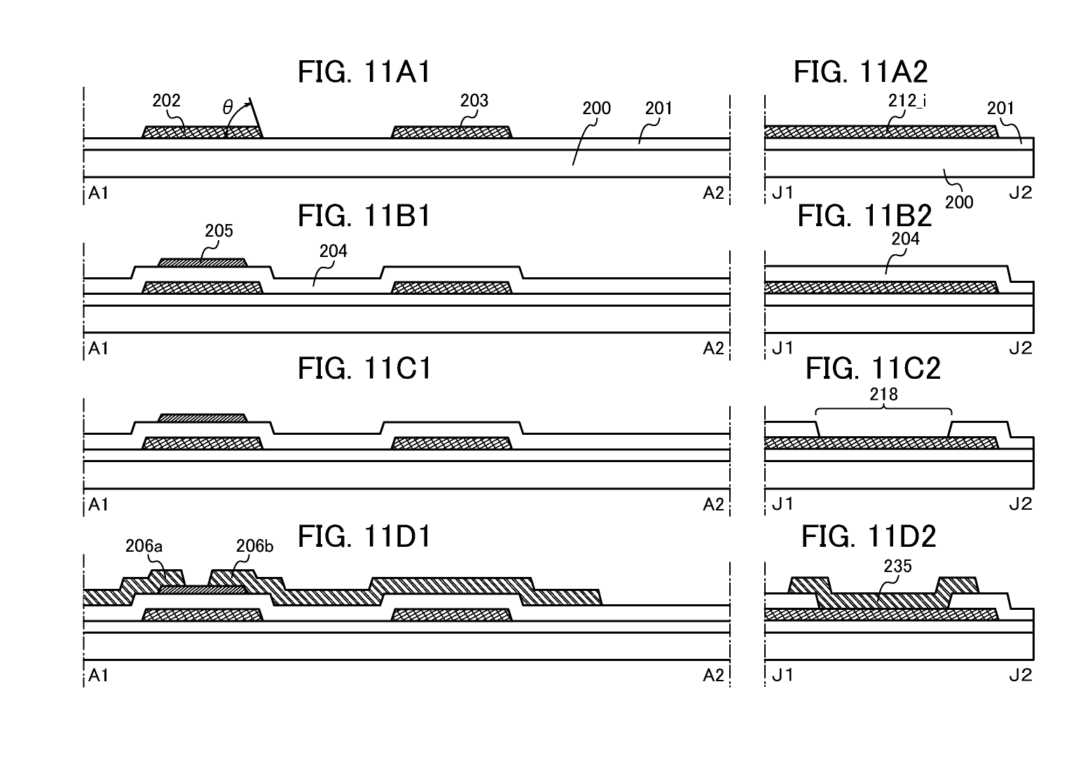

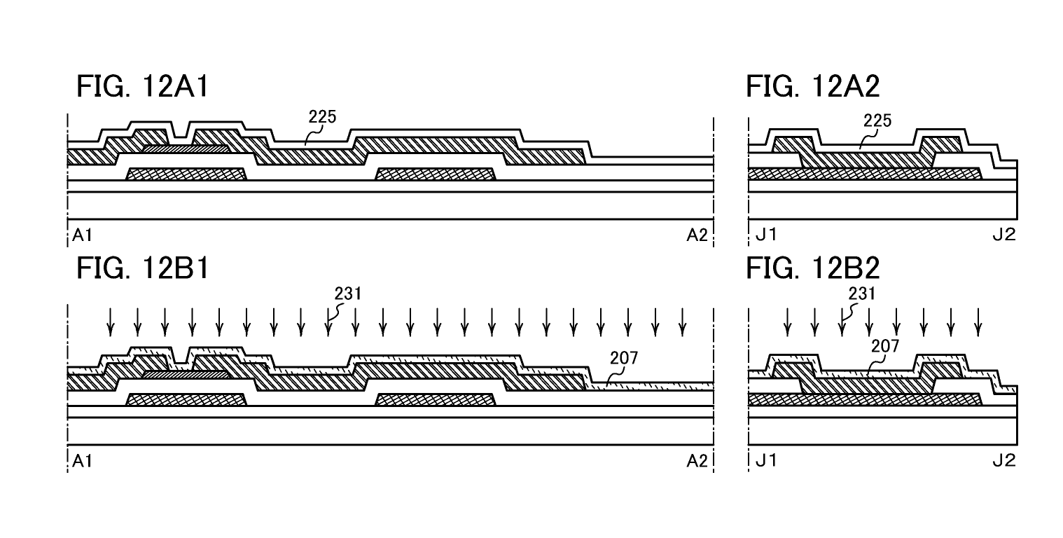

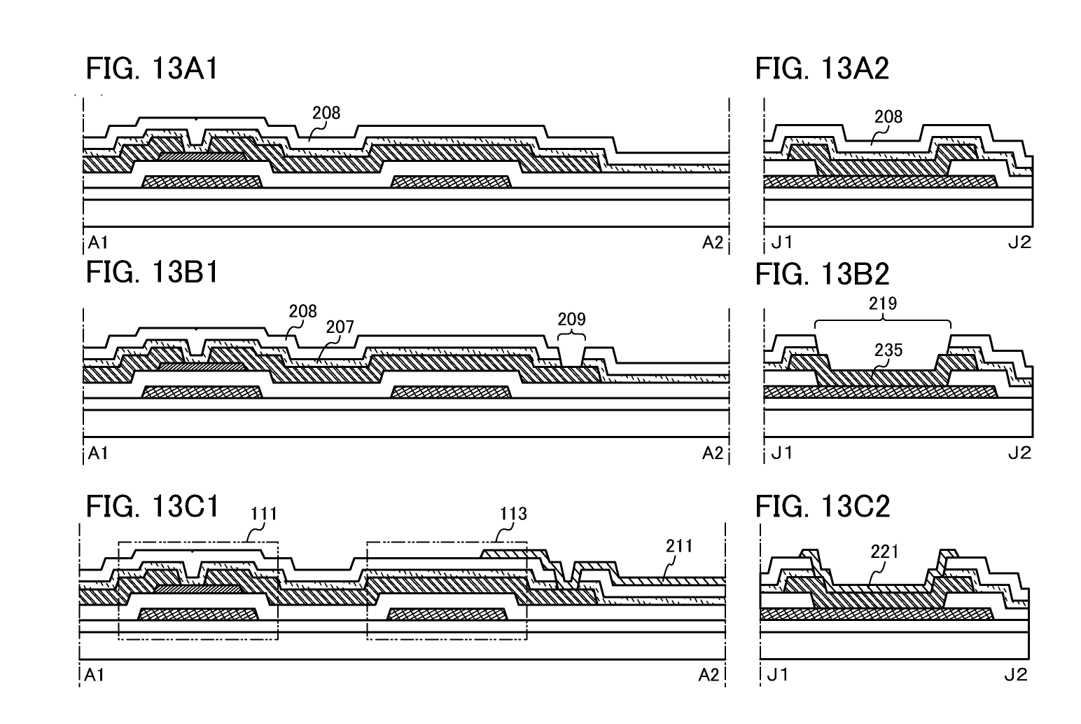

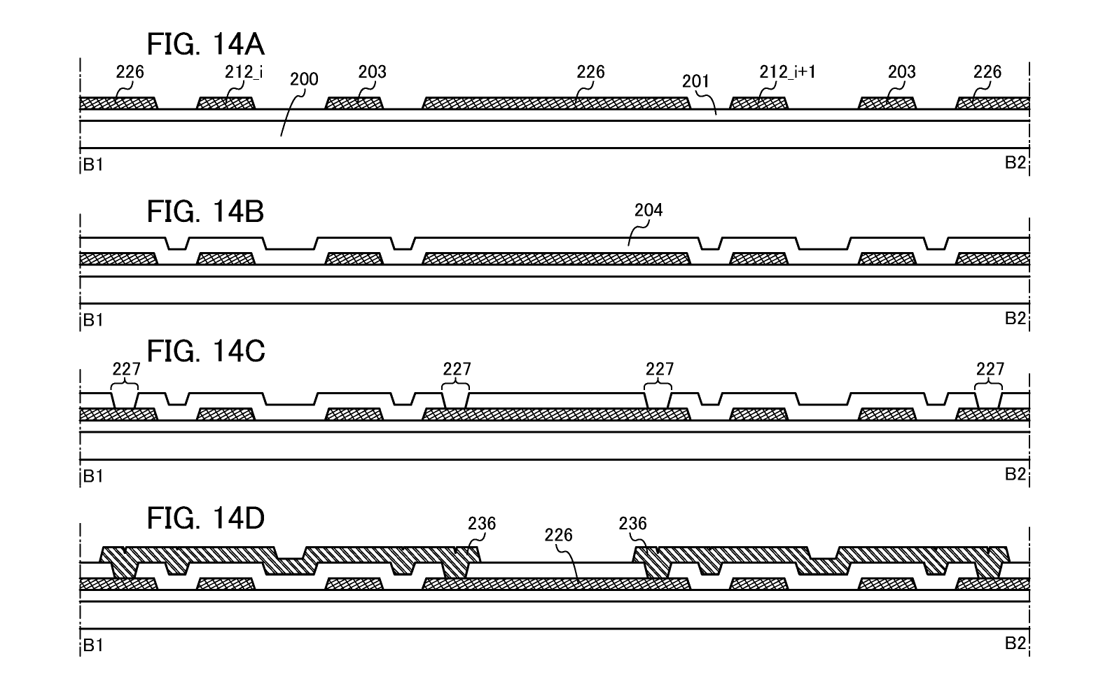

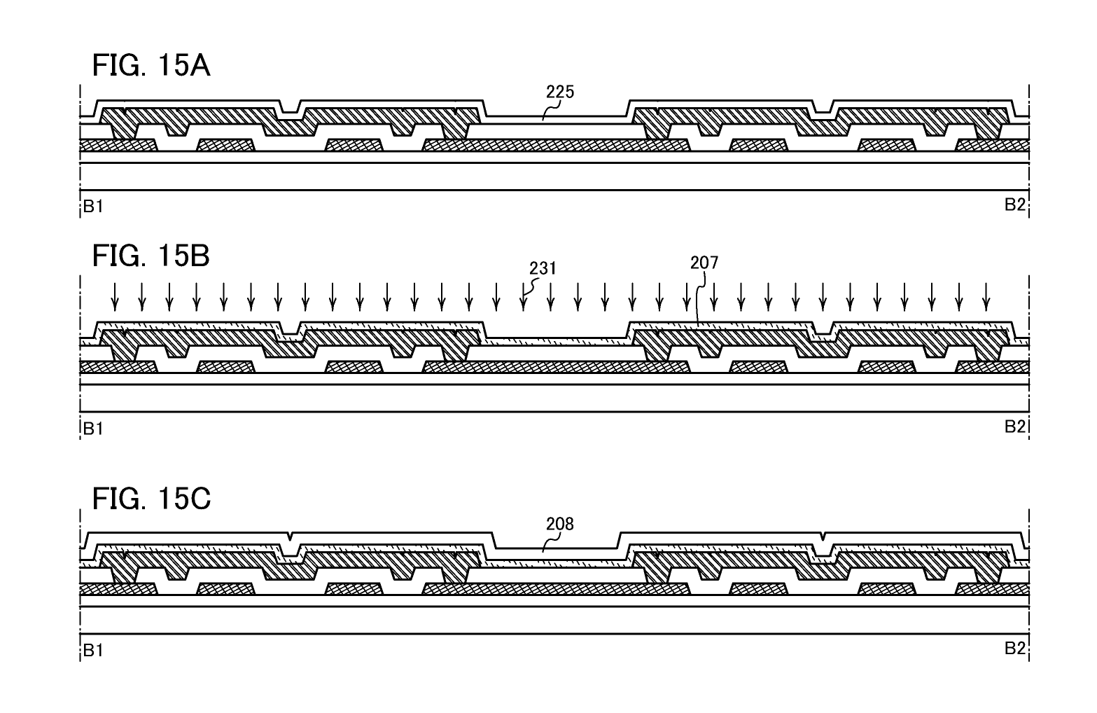

In this embodiment, examples of a configuration and a manufacturing method of a semiconductor device in which wiring resistance is reduced are described with reference to FIG. 1, FIGS. 2A and 2B, FIG. 3, FIG. 4, FIGS. 5A to 5C, FIG. 6, FIG. 7, FIGS. 8A and 8B, FIG. 9, FIGS. 10A1, 10A2, 10B1, and 10B2, FIGS. 11A1, 11A2, 11B1, 11B2, 11C1, 11C2, 11D1, and 11D2, FIGS. 12A1, 12A2, 12B1, and 12B2, FIGS. 13A1, 13A2, 13B1, 13B2, 13C1, and 13C2, FIGS. 14A to 14D, and FIGS. 15A to 15C. Note that in this embodiment, examples of application to a display device which is an embodiment of a semiconductor device are described.

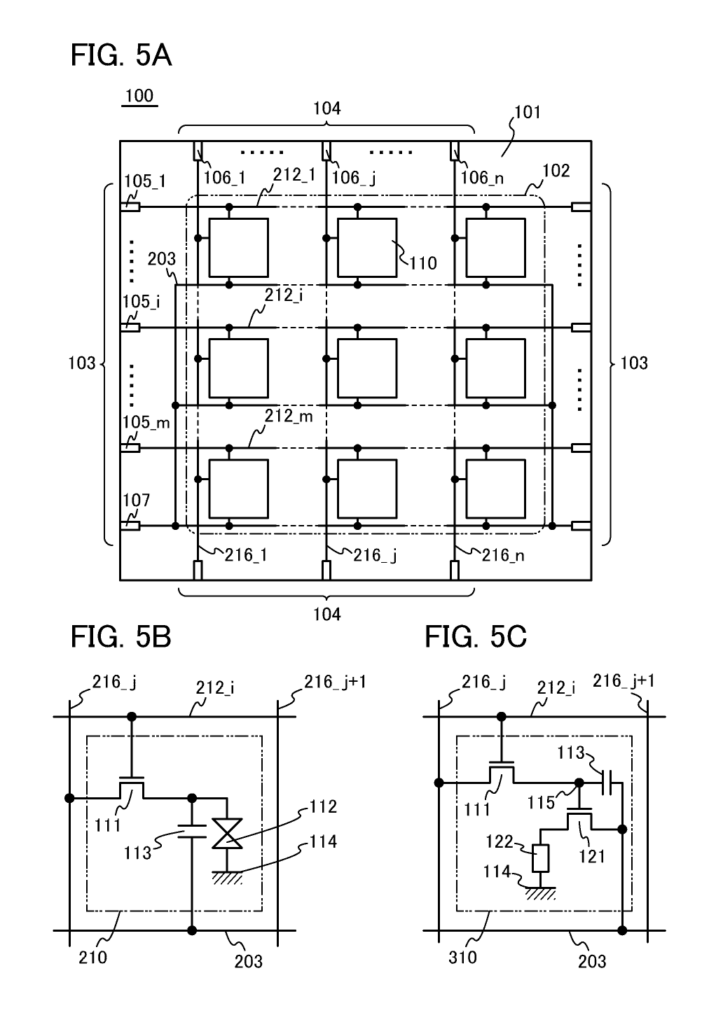

FIG. 5A illustrates an example of the configuration of a semiconductor device 100 that can be used in a display device. The semiconductor device 100 includes a pixel region 102, a terminal portion 103 including m terminals 105 (m is an integer of greater than or equal to 1) and a terminal 107, and a terminal portion 104 including n terminals 106 (n is an integer of greater than or equal to 1) over a substrate 101. Further, the semiconductor device 100 includes m wirings 212 and a wiring 203 that are electrically connected to the terminal portion 103, and n wirings 216 that are electrically connected to the terminal portion 104. The pixel region 102 includes a plurality of pixels 110 arranged in a matrix of m rows and n columns. A pixel 110(i,j) in the i_th row and the j_th column (i is an integer of greater than or equal to 1 and less than or equal to m, and j is an integer of greater than or equal to 1 and less than or equal to n) is electrically connected to a wiring 212_{—}i extending in the row direction and a wiring 216_{—}j extending in the column direction. In addition, each pixel is connected to the wiring 203 serving as a capacitor electrode or a capacitor wiring, and the wiring 203 is electrically connected to the terminal 107. The wiring 212_{—}i is electrically connected to a terminal 105_{—}i, and the wiring 216_{—}j is electrically connected to a terminal 106_{—}j.

The terminal portion 103 and the terminal portion 104 are external input terminals and are connected to external control circuits with flexible printed circuits (FPCs) or the like. Signals supplied from the external control circuits are input to the semiconductor device 100 through the terminal portion 103 and the terminal portion 104. In FIG. 5A, such terminal portions 103 are provided on the right and left of the pixel region 102, so that signals are input from two directions. Further in FIG. 5A, such terminal portions 104 are provided above and below the pixel region 102, so that signals are input from two directions. By inputting signals from two directions, signal supply capability is increased and high-speed operation of the semiconductor device 100 is facilitated. In addition, influences of signal delay due to an increase in size of the semiconductor device 100 or an increase in wiring resistance that accompanies an increase in definition can be reduced. Moreover, the semiconductor device 100 can have redundancy, so that reliability of the semiconductor device 100 can be improved. Although two terminal portions 103 and two terminal portions 104 are provided in FIG. 5A, a structure in which one terminal portion 103 and one terminal portion 104 are provided may also be employed.

FIG. 5B illustrates a pixel 210 which is an example of a circuit configuration applicable to the pixel 110 in the case where the semiconductor device 100 is used as a liquid crystal display device. The pixel 210 in FIG. 5B includes a transistor 111, a liquid crystal element 112, and a capacitor 113. A gate electrode of the transistor 111 is electrically connected to the wiring 212_{—}i, and one of a source electrode and a drain electrode of the transistor 111 is electrically connected to the wiring 216_{—}j. The other of the source electrode and the drain electrode of the transistor 111 is electrically connected to one electrode of the liquid crystal element 112 and one electrode of the capacitor 113. The other electrode of the liquid crystal element 112 is electrically connected to an electrode 114. The potential of the electrode 114 may be a fixed potential, e.g., 0 V, GND, or a common potential. The other electrode of the capacitor 113 is electrically connected to the wiring 203.

The transistor 111 has a function of selecting whether an image signal supplied from the wiring 216_{—}j is input to the liquid crystal element 112. After a signal that turns on the transistor 111 is supplied to the wiring 212_{—}i, an image signal is supplied to the liquid crystal element 112 from the wiring 216_through the transistor 111. The transmittance of light is controlled in accordance with the image signal (potential) supplied to the liquid crystal element 112. The capacitor 113 has a function as a storage capacitor (also referred to as a Cs capacitor) for holding a potential supplied to the liquid crystal element 112. With the capacitor 113, variation in the potential applied to the liquid crystal element 112, which is caused by a current flowing between a source electrode and a drain electrode in an off state of the transistor 111 (off-state current), can be suppressed.

FIG. 5C illustrates a pixel 310 which is an example of a circuit configuration applicable to the pixel 110 in the case where the semiconductor device 100 is used as an EL display device. The pixel 310 in FIG. 5C includes a transistor 111, a transistor 121, an EL element 122, and a capacitor 113. A gate electrode of the transistor 111 is electrically connected to the wiring 212_{—}i, and one of a source electrode and a drain electrode of the transistor 111 is electrically connected to the wiring 216_{—}j. The other of the source electrode and the drain electrode of the transistor 111 is electrically connected to a node 115 to which a gate electrode of the transistor 121 and one electrode of the capacitor 113 are electrically connected. In addition, one of a source electrode and a drain electrode of the transistor 121 is electrically connected to one electrode of the EL element 122, and the other of the source electrode and the drain electrode of the transistor 121 is electrically connected to the other electrode of the capacitor 113 and the wiring 203. The other electrode of the EL element 122 is electrically connected to the electrode 114. The potential of the electrode 114 may be a fixed potential, e.g., 0 V, GND, or a common potential. The difference between the potential of the wiring 203 and the potential of the electrode 114 is set so as to be larger than the total voltage of the threshold voltage of the transistor 121 and the threshold voltage of the EL element 122.

The transistor 111 has a function of selecting whether an image signal supplied from the wiring 216_{—}j is input to the gate electrode of the transistor 121. After a signal that turns on the transistor 111 is supplied to the wiring 212_{—}i, an image signal is supplied to the node 115 from the wiring 216_{—}j through the transistor 111.

The transistor 121 has a function of flowing current that corresponds to the potential (image signal) supplied to the node 115, to the EL element 122. The capacitor 113 has a function of keeping the difference between the potential of the node 115 and the potential of the wiring 203 constant. The transistor 121 has a function as a source of current for flowing current that corresponds to the image signal to the EL element 122.

It is possible to use an oxide semiconductor for the semiconductor layer in which a channel is formed in the transistor 111. An oxide semiconductor has an energy gap that is as wide as greater than or equal to 3.0 eV, and thus has high transmittance with respect to visible light. In a transistor obtained by processing an oxide semiconductor under appropriate conditions, the off-state current at ambient temperature (e.g., 25° C.) can be less than or equal to 100 zA (1×10⁻¹⁹ A), less than or equal to 10 zA (1×10⁻²⁰ A), and further less than or equal to 1 zA (1×10⁻²¹ A). Therefore, a semiconductor device with low power consumption can be achieved. Since by using an oxide semiconductor for the semiconductor layer, the potential applied to the liquid crystal element 112 can be held without provision of the capacitor 113, the aperture ratio of the pixel can be increased; accordingly, a display device with high display quality and low power consumption can be provided.

An oxide semiconductor used for the semiconductor layer is preferably an i-type (intrinsic) or substantially i-type oxide semiconductor obtained by reducing impurities such as moisture or hydrogen and reducing oxygen vacancies in the oxide semiconductor.

Note that an oxide semiconductor which is purified (purified OS) by reduction of impurities such as moisture or hydrogen which serves as an electron donor (donor) can be made to be an i-type (intrinsic) oxide semiconductor or an oxide semiconductor extremely close to an i-type oxide semiconductor (a substantially i-type oxide semiconductor) by supplying oxygen to the oxide semiconductor to reduce oxygen vacancies in the oxide semiconductor. A transistor including the i-type or substantially i-type oxide semiconductor in a semiconductor layer in which a channel is formed has characteristics of very small off-state current. Specifically, the hydrogen concentration in the purified OS which is measured by secondary ion mass spectrometry (SIMS) is less than or equal to 5×10¹⁹/cm³, preferably less than or equal to 5×10¹⁸/cm³, and further preferably less than or equal to 5×10¹⁷/cm³.

In addition, the carrier density of the i-type or substantially i-type oxide semiconductor, which is measured by Hall effect measurement, is less than 1×10¹⁴/cm³, preferably less than 1×10¹²/cm³, further preferably less than 1×10¹¹/cm³. Furthermore, the band gap of the oxide semiconductor is 2 eV or more, preferably 2.5 eV or more, further preferably 3 eV or more. With the use of the i-type or substantially i-type oxide semiconductor for a semiconductor layer in which a channel is formed, off-state current of the transistor can be reduced.

The analysis of the hydrogen concentration in the oxide semiconductor by SIMS is described here. It is known to be difficult to obtain accurate data in the proximity of a surface of a sample or in the proximity of an interface between stacked films formed of different materials by the SIMS analysis in principle. Thus, in the case where the distribution of the hydrogen concentration in the thickness direction of a film is analyzed by SIMS, the average value of the hydrogen concentration in a region of the film where almost the same value can be obtained without significant variation is employed as the hydrogen concentration. Further, in the case where the thickness of the film is small, a region where almost the same value can be obtained cannot be found in some cases due to the influence of the hydrogen concentration of an adjacent film. In this case, the maximum value or the minimum value of the hydrogen concentration in a region where the film is provided is employed as the hydrogen concentration of the film. Furthermore, in the case where a maximum value peak and a minimum value valley do not exist in the region where the film is provided, the value of the inflection point is employed as the hydrogen concentration.

An oxide semiconductor used for the semiconductor layer in which a channel is formed preferably contains at least indium (In) or zinc (Zn). In particular, In and Zn are preferably contained. In addition, as a stabilizer for reducing variation in electric characteristics of the transistor using the oxide semiconductor, gallium (Ga) is preferably contained. Tin (Sn) is preferably contained as a stabilizer. Hafnium (Hf) is preferably contained as a stabilizer. Aluminum (Al) is preferably contained as a stabilizer.

As another stabilizer, one or more kinds of lanthanoid selected from lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu) may be contained.

As the oxide semiconductor, for example, indium oxide, tin oxide, zinc oxide, a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide, a three-component metal oxide such as an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, or a four-component metal oxide such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide can be used. Further, SiO₂ may be contained in the above oxide semiconductor.

Here, for example, the In—Ga—Zn-based oxide means an oxide containing indium (In), gallium (Ga), and zinc (Zn) and there is no particular limitation on the ratio of In:Ga:Zn. The In—Ga—Zn-based oxide may contain a metal element other than In, Ga, and Zn. In this case, the amount of oxygen in the oxide semiconductor preferably exceeds the stoichiometric proportion of oxygen. With the excess oxygen, generation of carriers attributed to oxygen vacancies in the oxide semiconductor can be suppressed.

For the oxide semiconductor layer, a thin film represented by a chemical formula InMO₃(ZnO)ₘ (m>0) can be used, in which M denotes one or more metal elements selected from Sn, Zn, Ga, Al, Mn, and Co. Alternatively, a material represented by In₂SnO₅(ZnO)ₙ (n>0) may be used for the oxide semiconductor layer.

For example, an In—Ga—Zn-based oxide with an atomic ratio of In:Ga:Zn=1:1:1 (=1/3:1/3:1/3) or In:Ga:Zn=2:2:1 (=2/5:2/5:1/5), or any of oxides whose composition is in the neighborhood of the above compositions can be used. Alternatively, an In—Sn—Zn-based oxide with an atomic ratio of In:Sn:Zn=1:1:1 (=1/3:1/3:1/3), In:Sn:Zn=2:1:3 (=1/3:1/6:1/2), or In:Sn:Zn=2:1:5 (=1/4:1/8:5/8), or any of oxides whose composition is in the neighborhood of the above compositions may be used.

However, without limitation to the materials given above, a material with a composition suitable for requisite semiconductor characteristics (e.g., mobility, threshold voltage, and variation) may be used. Further, in order to obtain the requisite semiconductor characteristics, it is preferable that the carrier concentration, the impurity concentration, the defect density, the atomic ratio between a metal element and oxygen, the interatomic distance, the density, and the like be set to appropriate values.

For example, high mobility can be obtained relatively easily with an In—Sn—Zn-based oxide. However, the mobility can be increased by reducing the defect density in a bulk, even with an In—Ga—Zn-based oxide.

Note that for example, the “composition of an oxide containing In, Ga, and Zn at the atomic ratio, In:Ga:Zn=a:b:c (a+b+c=1), is in the neighborhood of the composition of an oxide containing In, Ga, and Zn at the atomic ratio, In:Ga:Zn=A:B:C (A+B+C=1)” means that a, b, and c satisfy the following relation: (a−A)²+(b−B)²+(c−C)²≦r², where r may be 0.05, for example. The same applies to other oxides.

The oxide semiconductor layer may be either single crystal or non-single-crystal. In the latter case, the oxide semiconductor may be either amorphous or polycrystal. Further, the oxide semiconductor may have a structure including a crystalline portion in an amorphous portion.

In an oxide semiconductor in an amorphous state, a flat surface can be obtained relatively easily, so that interface scattering in a transistor formed using the oxide semiconductor can be suppressed, whereby relatively high mobility can be obtained relatively easily.

In the case where an In—Zn-based oxide material is used as the oxide semiconductor, the atomic ratio, In/Zn is greater than or equal to 0.5 and less than or equal to 50, preferably greater than or equal to 1 and less than or equal to 20, further preferably greater than or equal to 1.5 and less than or equal to 15. When the atomic ratio of Zn is in the above preferred range, the field-effect mobility of the transistor can be improved. Here, when the atomic ratio of the compound is In:Zn:O=X:Y:Z, the relation Z>1.5X+Y is satisfied.

An oxide semiconductor layer may be in a non-single-crystal state, for example. The non-single-crystal state is, for example, structured by at least one of c-axis aligned crystal (CAAC), polycrystal, microcrystal, and an amorphous part. The density of defect states of an amorphous part is higher than those of microcrystal and CAAC. The density of defect states of microcrystal is higher than that of CAAC. Note that an oxide semiconductor including CAAC is referred to as a CAAC-OS (c-axis aligned crystalline oxide semiconductor).

For example, an oxide semiconductor layer may include a CAAC-OS. In the CAAC-OS, for example, c-axes are aligned, and a-axes and/or b-axes are not macroscopically aligned.

For example, an oxide semiconductor layer may include microcrystal. Note that an oxide semiconductor including microcrystal is referred to as a microcrystalline oxide semiconductor. A microcrystalline oxide semiconductor layer includes microcrystal (also referred to as nanocrystal) with a size greater than or equal to 1 nm and less than 10 nm, for example. Alternatively, a microcrystalline oxide semiconductor layer, for example, includes a crystal-amorphous mixed phase structure where crystal parts (each of which is greater than or equal to 1 nm and less than 10 nm) are distributed.

For example, an oxide semiconductor layer may include an amorphous part. Note that an oxide semiconductor including an amorphous part is referred to as an amorphous oxide semiconductor. An amorphous oxide semiconductor layer, for example, has disordered atomic arrangement and no crystalline component. Alternatively, an amorphous oxide semiconductor layer is, for example, absolutely amorphous and has no crystal part.

Note that an oxide semiconductor layer may be a mixed layer including any of a CAAC-OS, a microcrystalline oxide semiconductor, and an amorphous oxide semiconductor. The mixed layer, for example, includes a region of an amorphous oxide semiconductor, a region of a microcrystalline oxide semiconductor, and a region of a CAAC-OS. Further, the mixed layer may have a stacked structure including a region of an amorphous oxide semiconductor, a region of a microcrystalline oxide semiconductor, and a region of a CAAC-OS, for example.

Note that an oxide semiconductor layer may be in a single-crystal state, for example.

An oxide semiconductor layer preferably includes a plurality of crystal parts. In each of the crystal parts, a c-axis is preferably aligned in a direction parallel to a normal vector of a surface where the oxide semiconductor layer is formed or a normal vector of a surface of the oxide semiconductor layer. Note that, among crystal parts, the directions of the a-axis and the b-axis of one crystal part may be different from those of another crystal part. An example of such an oxide semiconductor layer is a CAAC-OS layer.

The CAAC-OS layer is not absolutely amorphous. The CAAC-OS layer, for example, includes an oxide semiconductor with a crystal-amorphous mixed phase structure where crystal parts and amorphous parts are intermingled. Note that in most cases, the crystal part fits inside a cube whose one side is less than 100 nm. In an image obtained with a transmission electron microscope (TEM), a boundary between an amorphous part and a crystal part and a boundary between crystal parts in the CAAC-OS layer are not clearly detected. Further, with the TEM, a grain boundary in the CAAC-OS layer is not clearly found. Thus, in the CAAC-OS layer, a reduction in electron mobility due to the grain boundary is suppressed.

In each of the crystal parts included in the CAAC-OS layer, for example, a c-axis is aligned in a direction parallel to a normal vector of a surface where the CAAC-OS layer is formed or a normal vector of a surface of the CAAC-OS layer. Further, in each of the crystal parts, metal atoms are arranged in a triangular or hexagonal configuration when seen from the direction perpendicular to the a-b plane, and metal atoms are arranged in a layered manner or metal atoms and oxygen atoms are arranged in a layered manner when seen from the direction perpendicular to the c-axis. Note that, among crystal parts, the directions of the a-axis and the b-axis of one crystal part may be different from those of another crystal part. In this specification, a term “perpendicular” includes a range from 80° to 100°, preferably from 85° to 95°. In addition, a term “parallel” includes a range from −10° to 10°, preferably from −5° to 5°.

In the CAAC-OS layer, distribution of crystal parts is not necessarily uniform. For example, in the formation process of the CAAC-OS layer, in the case where crystal growth occurs from a surface side of the oxide semiconductor layer, the proportion of crystal parts in the vicinity of the surface of the oxide semiconductor layer is higher than that in the vicinity of the surface where the oxide semiconductor layer is formed in some cases. Further, when an impurity is added to the CAAC-OS layer, the crystal part in a region to which the impurity is added becomes amorphous in some cases.

Since the c-axes of the crystal parts included in the CAAC-OS layer are aligned in the direction parallel to a normal vector of a surface where the CAAC-OS layer is formed or a normal vector of a surface of the CAAC-OS layer, the directions of the c-axes may be different from each other depending on the shape of the CAAC-OS layer (the cross-sectional shape of the surface where the CAAC-OS layer is formed or the cross-sectional shape of the surface of the CAAC-OS layer). Note that the film deposition is accompanied with the formation of the crystal parts or followed by the formation of the crystal parts through crystallization treatment such as heat treatment. Hence, the c-axes of the crystal parts are aligned in the direction parallel to a normal vector of the surface where the CAAC-OS layer is formed or a normal vector of the surface of the CAAC-OS layer.

In a transistor using the CAAC-OS, change in electric characteristics due to irradiation with visible light or ultraviolet light is small. Thus, the transistor has high reliability.

In order that the oxide semiconductor layer may be the CAAC-OS, the surface where the oxide semiconductor layer is formed is preferably amorphous. When the surface where the oxide semiconductor layer is formed is crystalline, crystallinity of the oxide semiconductor layer is easily disordered and the CAAC-OS is not easily formed.

Note that the surface where the oxide semiconductor layer is formed may have a CAAC structure. In the case where the surface where the oxide semiconductor layer is formed has the CAAC structure, the oxide semiconductor layer easily becomes the CAAC-OS.

Therefore, in order that the oxide semiconductor layer may be the CAAC-OS, it is preferable that the surface where the oxide semiconductor layer is formed be an amorphous or have the CAAC structure.

Nitrogen may be substituted for part of constituent oxygen of the oxide semiconductor.

Further, in an oxide semiconductor having a crystal part such as the CAAC-OS, defects in the bulk can be further reduced, and mobility higher than that of an oxide semiconductor in an amorphous state can be obtained by improving the surface flatness. To improve the surface flatness, the oxide semiconductor is preferably formed on a flat surface. Specifically, the oxide semiconductor may be formed on a surface with an average surface roughness (Ra) of less than or equal to 1 nm, preferably less than or equal to 0.3 nm, further preferably less than or equal to 0.1 nm. Ra can be measured using an atomic force microscope (AFM).

Since the transistor described in this embodiment is a bottom-gate transistor, a gate electrode 202 and an insulating layer 204 serving as a gate insulating layer are positioned under the oxide semiconductor film. Thus, in order to obtain the above-described flat surface, planarization treatment such as chemical mechanical polishing (CMP) treatment may be performed at least on a surface of the insulating layer 204, which overlaps with the gate electrode 202, after the gate electrode 202 and the insulating layer 204 are formed over the substrate.

The oxide semiconductor layer 205 has a thickness greater than or equal to 1 nm and less than or equal to 30 nm (preferably greater than or equal to 5 nm and less than or equal to 10 nm) and can be formed by a sputtering method, a molecular beam epitaxy (MBE) method, a CVD method, a pulsed laser deposition method, an atomic layer deposition (ALD) method, or the like as appropriate. The oxide semiconductor layer 205 may be formed with a sputtering apparatus which performs deposition with surfaces of a plurality of substrates set substantially perpendicular to a surface of a sputtering target.

Description of this embodiment is given on the assumption that the transistor is an n-channel transistor.

Next, an example of the configuration of the pixel 110 illustrated in FIG. 5A is described with reference to FIG. 1 and FIGS. 2A and 2B. FIG. 1 is a plan view illustrating a plan structure of the pixel 110 illustrated in FIG. 5A, and FIGS. 2A and 2B are cross-sectional views illustrating a stacked structure of the pixel 110 illustrated in FIG. 5A. Note that chain lines A1-A2 and B1-B2 in FIG. 1 correspond to cross sections A1-A2 and B1-B2 in FIGS. 2A and 2B, respectively. For easy viewing, some components are omitted in FIG. 1.

In the transistor 111 in FIG. 1, a drain electrode 206b is surrounded by a source electrode 206a that is U-shaped (or C-shaped, square-bracket-like shaped, or horseshoe-shaped). With such a shape, an enough channel width can be ensured even when the area of the transistor is small, and accordingly, the amount of current flowing at the time of conduction of the transistor (also referred to as on-state current) can be increased.

If parasitic capacitance generated between the gate electrode 202 and the drain electrode 206b electrically connected to a pixel electrode 211 is larger than parasitic capacitance generated between the gate electrode 202 and the source electrode 206a, the pixel electrode 211 is easily influenced by feedthrough, which may cause degradation in display quality because the potential supplied to the liquid crystal element 112 cannot be held accurately. With the structure in which the source electrode 206a is U-shaped and surrounds the drain electrode 206b as described in this embodiment, an enough channel width can be ensured and parasitic capacitance generated between the drain electrode 206b and the gate electrode 202 can be reduced. Therefore, the display quality of a display device can be improved. Further, the gate electrode 202 is connected to the wiring 212_{—}i, and the source electrode 206a is connected to a wiring 236. In FIG. 1 and FIGS. 2A and 2B, an example where the wiring 216_{—}j includes the wiring 236 and a wiring 226 and electrically connects the wiring 236 and the wiring 226 in series is shown.

The cross section A1-A2 in FIG. 2A shows the stacked structure of the transistor 111 and the stacked structure of the capacitor 113. The transistor 111 has one kind of bottom-gate structure called a channel-etched type.

In the cross section A1-A2 in FIG. 2A, an insulating layer 201 is formed over a substrate 200, and the gate electrode 202 and the wiring 203 are formed over the insulating layer 201. Over the gate electrode 202 and the wiring 203, the insulating layer 204 and the oxide semiconductor layer 205 are formed. Over the oxide semiconductor layer 205, the source electrode 206a and the drain electrode 206b are formed. Further, an insulating layer 207 is formed over the source electrode 206a and the drain electrode 206b so as to be in contact with part of the oxide semiconductor layer 205, and an insulating layer 208 is formed over the insulating layer 207. The pixel electrode 211 is formed over the insulating layer 208 and is electrically connected to the drain electrode 206b through a contact hole 209 formed in the insulating layers 207 and 208.

The gate electrode 202, the wiring 212_{—}i, the wiring 203, and the wiring 226 can be formed using the same conductive layer. When the gate electrode 202, the wiring 212_{—}i, the wiring 203, and the wiring 226 are formed using a conductive material containing copper (Cu), increase in wiring resistance can be prevented. Further, a conductive layer containing Cu and a conductive layer containing a metal element having a higher melting point than Cu, such as tungsten (W), tantalum (Ta), molybdenum (Mo), titanium (Ti), or chromium (Cr), or a nitride or an oxide of the above metal element are stacked as the gate electrode 202, the wiring 212_{—}i, the wiring 203, and the wiring 226; thus, migration is suppressed and reliability of the semiconductor device can be improved. For example, a stack of tantalum nitride and copper is used.

The insulating layer 204 is preferably formed using a material having barrier properties for preventing Cu diffusion. Examples of the material having barrier properties include silicon nitride and aluminum oxide. A wiring containing Cu is covered with an insulating layer having barrier properties, whereby Cu diffusion can be suppressed.

The source electrode 206a and the drain electrode 206b (including a wiring formed using the same layer as the source electrode and the drain electrode) formed in contact with the oxide semiconductor layer 205 are preferably formed without using Cu. When Cu is used for the source electrode 206a and the drain electrode 206b formed in contact with the oxide semiconductor layer 205, Cu etched when the source electrode 206a and the drain electrode 206b are formed is diffused into the oxide semiconductor layer 205; thus, electric characteristics and reliability of the transistor deteriorate. Note that the source electrode 206a and the drain electrode 206b may be a single layer or a plurality of layers. For example, a three-layer structure of tungsten, aluminum, and titanium may be used.

A portion in which the wiring 203 and the drain electrode 206b overlap with each other with the insulating layer 204 interposed therebetween functions as the capacitor 113. Thus, the wiring 203 functions as a capacitor electrode or a capacitor wiring. The insulating layer 204 functions as a dielectric layer of the capacitor 113. For the dielectric layer of the capacitor 113, an oxide semiconductor may be used. The relative dielectric constant of an oxide semiconductor layer is as high as 14 to 16. Accordingly, when an oxide semiconductor is used for the oxide semiconductor layer 205, the capacitance value of the capacitor 113 can be increased. The dielectric layer formed between the wiring 203 and the drain electrode 206b may have a multi-layer structure. In the case where the dielectric layer is formed to have a multi-layer structure, even when a pinhole is generated in one dielectric layer, the pinhole is covered with another dielectric layer; accordingly, the capacitor 113 can operate normally.

The cross section B 1-B2 in FIG. 2B illustrates the stacked structure of the wiring 216_{—}j. In the cross section B1-B2 in FIG. 2B, the insulating layer 201 is formed over the substrate 200, and the wiring 226 is formed over the insulating layer 201. The insulating layer 204 is formed over the wiring 226, and the wiring 236 is formed over the insulating layer 204 and is electrically connected to the wiring 226 through a contact hole 227 formed in the insulating layer 204. The insulating layer 207 and the insulating layer 208 are formed over the wiring 236.

The wiring 216_{—}j includes a plurality of wirings 226 and a plurality of wirings 236. The wiring 226 is formed using the same layer as the wiring 212_{—}i and the wiring 203. The wiring 236 is formed using the same layer as the source electrode 206a and the drain electrode 206b. The wiring 236 is formed over the wiring 212_{—}i and the wiring 203 with the insulating layer 204 provided therebetween and electrically connects the adjacent wirings 226. The wiring 216_{—}j in FIG. 1 and FIGS. 2A and 2B has a structure in which the wiring 226 containing Cu and the wiring 236 are alternately electrically connected to each other. The wiring 226 containing Cu is covered with the insulating layer 204 having barrier properties; thus, Cu diffusion can be suppressed. As described above, when the wiring 216_{—}j is formed using a conductive material containing Cu, wiring resistance of the wiring 216_{—}j can be reduced without an increase in width and thickness of the wiring.

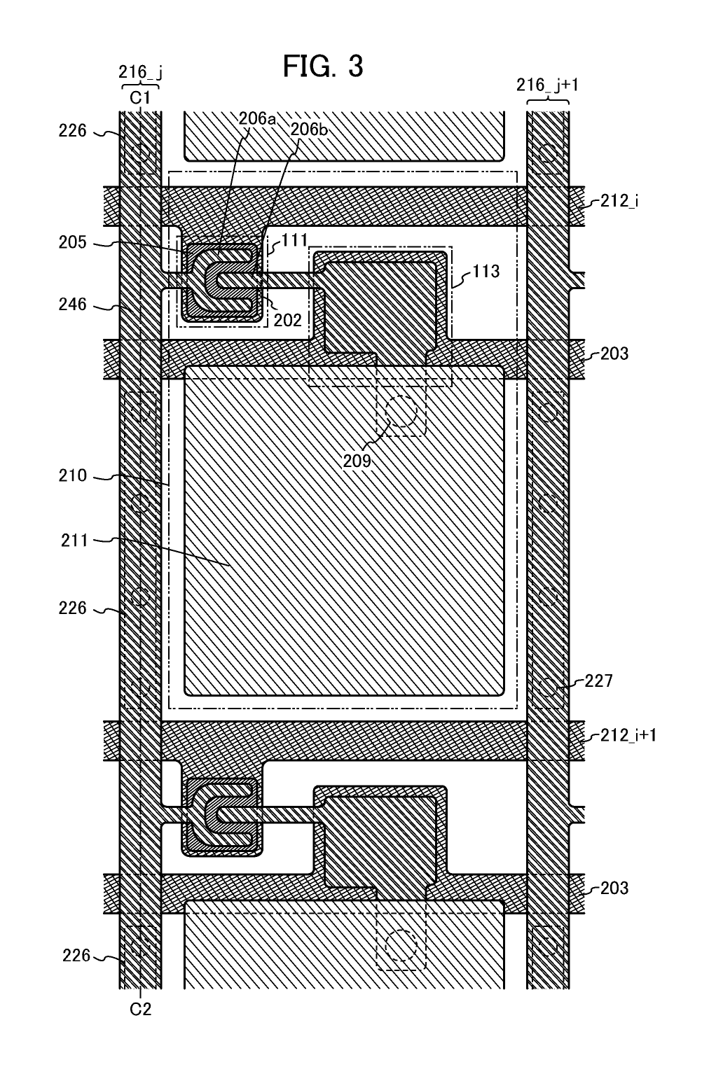

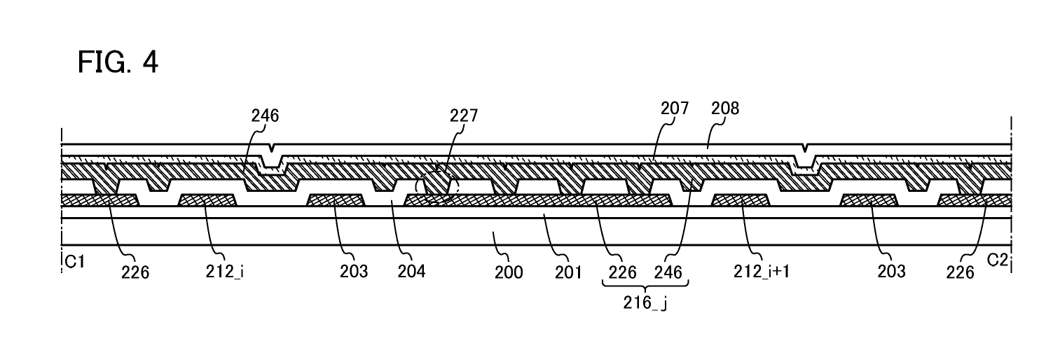

Next, the wiring 216_{—}j having a structure different from that in FIG. 1 and FIGS. 2A and 2B is described with reference to FIG. 3 and FIG. 4.

FIG. 3 is a top view illustrating a plan structure of the wiring 216_{—}j having a different structure from the wiring 216_{—}j in FIG. 1, and FIG. 4 is a cross-sectional view of a portion taken along chain line C1-C2 in FIG. 3. The cross section C1-C2 in FIG. 4 illustrates the stacked structure of the wiring 216_{—}j having a different structure from the wiring 216_{—}j in FIGS. 2A and 2B. For easy viewing, some components are omitted in FIG. 3.

The cross section C1-C2 in FIG. 4 illustrates the stacked structure of the wiring 216_{—}j in FIG. 3. In the cross section C1-C2 illustrated in FIG. 4, the insulating layer 201 is formed over the substrate 200, and the wiring 226 is formed over the insulating layer 201. The insulating layer 204 is formed over the wiring 226, and a wiring 246 is formed over the insulating layer 204 and is electrically connected to the wiring 226 through the contact hole 227 formed in the insulating layer 204. The insulating layer 207 and the insulating layer 208 are formed over the wiring 246.

The wiring 216_{—}j in FIG. 3 and FIG. 4 includes the wiring 246 and a plurality of wirings 226. The wiring 246 extends in the column direction and is electrically connected to the plurality of wirings 226 containing Cu; thus, wiring resistance of the wiring 216_{—}j can be reduced without an increase in width and thickness of the wiring. Note that the wiring 246 can be regarded as having a structure where the plurality of wirings 226 is connected to each other. In other words, the wiring 216_{—}j in FIG. 3 and FIG. 4 has a structure in which the wiring 246 and the wirings 226 are electrically connected to each other in parallel.

Further, the area of contact between the wiring 236 and the wiring 226 and the area of contact between the wiring 246 and the wiring 226 are preferably large. It is preferable to form a plurality of contact holes 227 over the wiring 226.

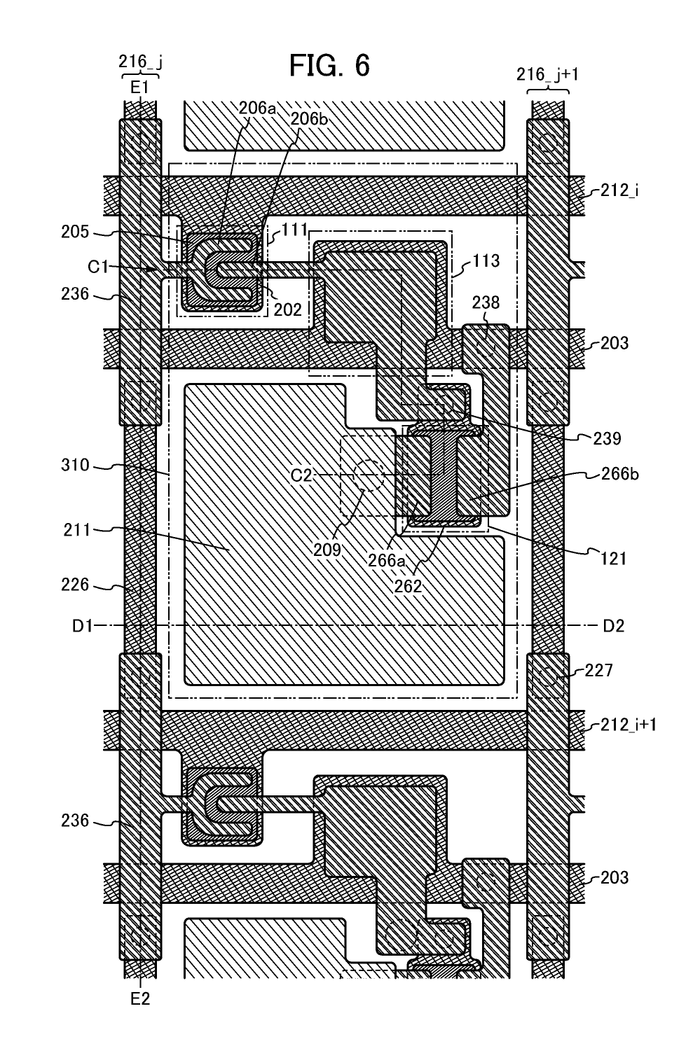

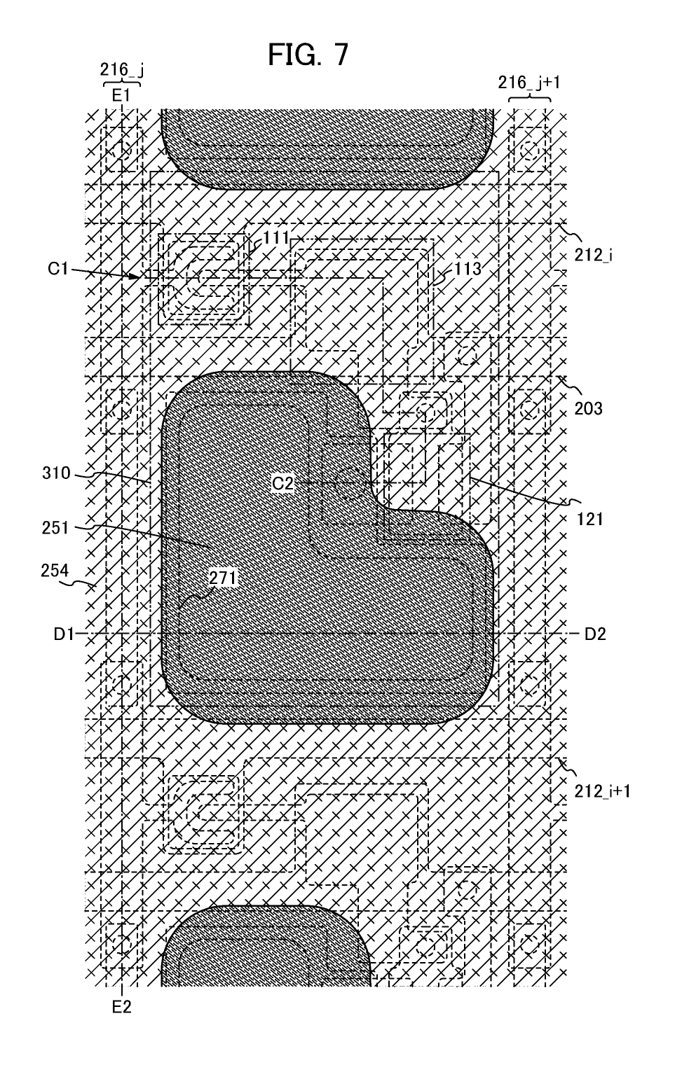

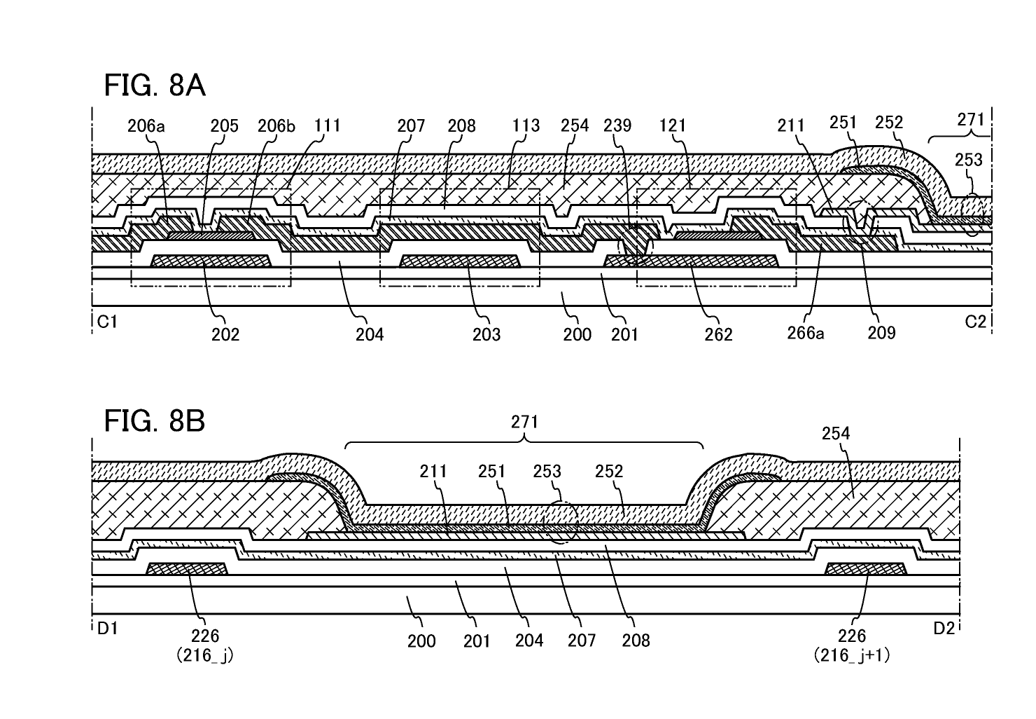

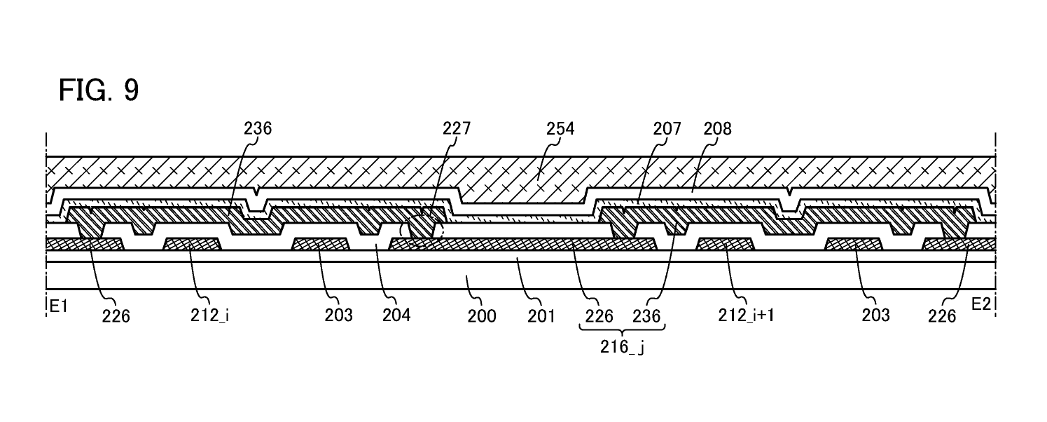

Next, an example of the configuration of the pixel 310 in FIG. 5C is described with reference to FIG. 6, FIG. 7, FIGS. 8A and 8B, and FIG. 9. FIG. 6 and FIG. 7 are top views illustrating a plan structure of the pixel 310. FIG. 6 is a top view illustrating the state where the uppermost layer is the pixel electrode 211, and FIG. 7 is a top view illustrating the state where a partition layer 254 and an EL layer 251 are further formed. For easy viewing, some components are omitted in FIG. 6 and FIG. 7.

FIGS. 8A and 8B and FIG. 9 are cross-sectional views illustrating the stacked structure of the pixel 310. FIG. 8A corresponds to a cross section taken along dashed-dotted line C1-C2 in FIG. 6 and FIG. 7, and FIG. 8B corresponds to a cross section taken along dashed-dotted line D1-D2 in FIG. 6 and FIG. 7. FIG. 9 corresponds to a cross section taken along dashed-dotted line E1-E2 in FIG. 6 and FIG. 7. Note that in FIG. 6, FIG. 7, FIGS. 8A and 8B, and FIG. 9, description of portions which are the same as those in the structures described with reference to FIG. 1, FIGS. 2A and 2B, FIG. 3, and FIG. 4 is omitted.

The cross section C1-C2 illustrated in FIG. 8A shows the stacked structures of the transistor 111, the transistor 121, and the capacitor 113. Note that the transistor 121 is a bottom-gate transistor, as the transistor 111.

In the cross section C1-C2 in FIG. 8A, the drain electrode 206b of the transistor 111 is electrically connected to a gate electrode 262 of the transistor 121 through a contact hole 239 formed in the insulating layer 204. A source electrode 266a of the transistor 121 is electrically connected to the pixel electrode 211. In FIG. 6 and FIG. 7, a drain electrode 266b of the transistor 121 is electrically connected to the wiring 203 through a contact hole 238 formed in the insulating layer 204.

The partition layer 254 for separating the EL layer 251 for each pixel is formed over the insulating layer 208. The EL layer 251 is formed over the pixel electrode 211 and the partition layer 254. An electrode 252 is formed over the partition layer 254 and the EL layer 251. In an opening 271, a portion where the pixel electrode 211, the EL layer 251, and the electrode 252 overlap with one another functions as an EL element 253.

In the cross section D1-D2 in FIG. 8B, the insulating layer 201 is formed over the substrate 200, the insulating layer 204 is formed over the insulating layer 201, and the wiring 226 is formed over the insulating layer 201. The insulating layer 204 is formed over the wiring 226, the insulating layer 207 is formed over the insulating layer 204, and the insulating layer 208 is formed over the insulating layer 207. Further, the pixel electrode 211 is formed over the insulating layer 207. The partition layer 254 is formed over the insulating layer 207, and the opening 271 is formed in a position which overlaps with the pixel electrode 211 of the partition layer 254.

The side surfaces of the partition layer 254 where the opening 271 is formed preferably have a taper shape or a shape with a curvature. With use of a photosensitive resin material for the partition layer 254, the side surfaces of the partition layer 254 can have a shape with a continuous curvature. As an organic insulating material for forming the partition layer 254, an acrylic resin, a phenol resin, polystyrene, polyimide, or the like can be used.

The pixel electrode 211 functions as one electrode of the EL element 253. The electrode 252 functions as the other electrode of the EL element 253. The electrode 252 can be formed using a material similar to that of the source electrode or the drain electrode of the transistor. In the case where the EL element has a bottom emission structure in which light is emitted from the EL element 253 from the substrate 200 side, the electrode 252 is preferably formed using a material with high light reflectance such as aluminum or silver.

The EL layer 251 may be formed by stacking a hole injection layer, a hole transport layer, a light-emitting layer, an electron transport layer, an electron injection layer, or the like. In the case where the pixel electrode 211 is used as an anode, a material having a high work function is used for the pixel electrode 211. In the case where the pixel electrode 211 has a stacked structure of a plurality of layers, a material having a high work function is used for at least a layer in contact with the EL layer 251. In the case where the electrode 252 is used as a cathode, a metal material having a low work function may be used for the electrode 252. Specifically, an alloy of aluminum and lithium can be used for the electrode 252. The electrode 252 may be a stack of an alloy layer of aluminum and lithium and a conductive layer.

An embodiment of the present invention can also be applied to a top emission structure in which light is emitted from the EL element 253 from the electrode 252 side or a dual emission structure in which light is emitted from the EL element 253 from both of the above-mentioned sides. In the case where the EL element 253 has a top emission structure, the pixel electrode 211 is used as a cathode, the electrode 252 is used as an anode, and the injection layers, transport layers, light-emitting layer, and the like of the EL layer 251 are stacked in the order reverse to the order of the bottom emission structure.

Note that a structure below the partition layer 254 of the cross section in FIG. 9 can be replaced with the structure in FIG. 4.

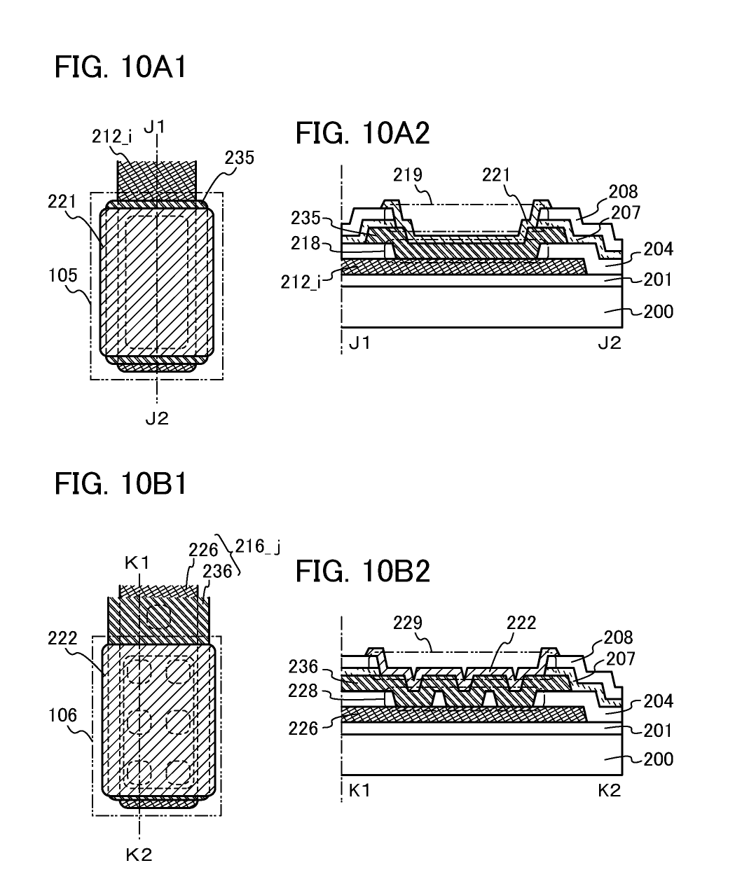

Next, examples of the structures of the terminal 105 and the terminal 106 are described with reference to FIGS. 10A1, 10A2, 10B1, and 10B2. FIGS. 10A1 and 10A2 are a top view and a cross-sectional view, respectively, of the terminal 105. A dashed-dotted line J1-J2 in FIG. 10A1 corresponds to a cross section J1-J2 in FIG. 10A2. FIGS. 10B1 and 10B2 are a top view and a cross-sectional view, respectively, of the terminal 106. A dashed-dotted line K1-K2 in FIG. 10B1 corresponds to a cross section K1-K2 in FIG. 10B2. In the cross sections J1-J2 and K1-K2, J2 and K2 correspond to end portions of the substrate.

For easy viewing, some components are omitted in FIGS. 10A1 and 10B1.

In the cross section J142, the insulating layer 201 is formed over the substrate 200, and the wiring 212_{—}i is formed over the insulating layer 201. The insulating layer 204 is formed over the wiring 212_{—}i, and an electrode 235 is formed over the insulating layer 204. The electrode 235 is electrically connected to the wiring 212_{—}i through a contact hole 218 formed in the insulating layer 204. Further, the insulating layer 207 and the insulating layer 208 are formed over the electrode 235, and an electrode 221 is formed over the insulating layer 208. The electrode 222 is electrically connected to the electrode 221 through a contact hole 219 formed in the insulating layer 207 and the insulating layer 208.

In the cross section K1-K2, the insulating layer 201 is formed over the substrate 200, and the wiring 226 is formed over the insulating layer 201. The insulating layer 204 is formed over the wiring 226, and the wiring 236 is formed over the insulating layer 204. The wiring 236 is electrically connected to the wiring 226 through a contact hole 228 formed in the insulating layer 204. FIGS. 10B1 and 10B2 illustrate an example where a plurality of contact holes is formed in the insulating layer 204; however, the number of contact holes may be one as in FIGS. 10A1 and 10A2. Further, the insulating layer 207 and the insulating layer 208 are formed over the wiring 236, and the electrode 222 is formed over the insulating layer 208. The electrode 222 is electrically connected to the wiring 236 through a contact hole 229 formed in the insulating layer 207 and the insulating layer 208. Note that the wiring 216_{—}j includes the wiring 226 and the wiring 236.

Note that the terminal 107 can have a structure similar to that of the terminal 105 or the terminal 106. The structure of the terminal 105 and that of the terminal 106 may be replaced with each other, and those of the terminals 105 and 106 may have the same structure.

Next, a method for manufacturing a pixel portion of the display device described with reference to FIG. 1 and FIGS. 2A and 2B and the terminal 105 described with reference to FIGS. 10A1 and 10A2 are described with reference to FIGS. 11A1, 11A2, 11B1, 11B2, 11C1, 11C2, 11D1, and 11D2, FIGS. 12A1, 12A2, 12B1, and 12B2, FIGS. 13A1, 13A2, 13B1, 13B2, 13C1, and 13C2, FIGS. 14A to 14D, and FIGS. 15A to 15C. In FIGS. 11A1, 11A2, 11B1, 11B2, 11C1, 11C2, 11D1, and 11D2, FIGS. 12A1, 12A2, 12B1, and 12B2, and FIGS. 13A1, 13A2, 13B1, 13B2, 13C1, and 13C2, cross sections A1-A2 are cross-sectional views of the portion taken along dashed-dotted line A1-A2 in FIG. 1 and cross sections J1-J2 are cross-sectional views of the portion taken along dashed-dotted line J1-J2 in FIGS. 10A1 and 10A2. Cross sections B1-B2 in FIGS. 14A to 14D and FIGS. 15A to 15C are cross-sectional views of the portion taken along dashed-dotted line B1-B2 in FIG. 1.

First, an insulating layer to be the insulating layer 201 is formed with a thickness of greater than or equal to 50 nm and less than or equal to 300 nm, preferably greater than or equal to 100 nm and less than or equal to 200 nm over the substrate 200 (see FIGS. 11A1 and 11A2 and FIG. 14A). As the substrate 200, as well as a glass substrate or a ceramic substrate, a plastic substrate or the like having heat resistance to withstand a process temperature in this manufacturing process can be used. In the case where a substrate does not need a light-transmitting property, a metal substrate such as a stainless alloy substrate with a surface provided with an insulating layer may be used. As the glass substrate, for example, an alkali-free glass substrate of barium borosilicate glass, aluminoborosilicate glass, aluminosilicate glass, or the like may be used. In addition, a quartz substrate, a sapphire substrate, or the like can be used. In this embodiment, a substrate of aluminoborosilicate glass is used as the substrate 200.

A flexible substrate may also be used as the substrate 200. In the case where a flexible substrate is used, the transistor, the capacitor, or the like may be directly formed over the flexible substrate, or the transistor, the capacitor, or the like may be formed over a manufacturing substrate, and then separated from the manufacturing substrate and transferred onto the flexible substrate. To separate and transfer the transistor, the capacitor, or the like from the manufacturing substrate to the flexible substrate, a separation layer may be provided between the manufacturing substrate and the transistor, the capacitor, or the like.

The insulating layer 201 functions as a base layer, and can prevent or reduce diffusion of an impurity element from the substrate 200. The insulating layer 201 is formed of a single layer or a stacked layer using one or more of materials selected from aluminum nitride, aluminum oxide, aluminum nitride oxide, aluminum oxynitride, gallium oxide, silicon nitride, silicon oxide, silicon nitride oxide, and silicon oxynitride. In this specification, a nitride oxide refers to a material containing a larger amount of nitrogen than oxygen, and an oxynitride refers to a material containing a larger amount of oxygen than nitrogen. The content of each element can be measured by Rutherford backscattering spectrometry (RBS), for example. The insulating layer 201 can be formed by a sputtering method, a CVD method, a coating method, a printing method, or the like.

Further, a halogen element such as chlorine or fluorine may be contained in the insulating layer 201, whereby the function of preventing or reducing diffusion of impurity elements from the substrate 200 can be further improved. The concentration of a halogen element contained in the insulating layer 201 is preferably greater than or equal to 1×10¹⁵/cm³ and less than or equal to 1×10²⁰/cm³ in its peak measured by secondary ion mass spectrometry (SIMS).

The insulating layer 201 can be formed by a sputtering method, an MBE method, a CVD method, a pulsed laser deposition method, an ALD method, or the like as appropriate. Alternatively, a high-density plasma CVD method using microwaves (e.g., a frequency of 2.45 GHz) or the like can be applied. The insulating layer 201 may be formed using a sputtering apparatus which performs deposition with surfaces of a plurality of substrates set substantially perpendicular to a surface of a sputtering target.

In this embodiment, as the insulating layer 201, a 200-nm-thick silicon oxynitride layer is formed over the substrate 200 by a plasma CVD method. Further, the temperature in the formation of the insulating layer 201 is preferably high as much as possible but is lower than or equal to the temperature that the substrate 200 can withstand. For example, the insulating layer 201 is formed while the substrate 200 is heated at a temperature higher than or equal to 350° C. and lower than or equal to 450° C. The temperature in the formation of the insulating layer 201 is preferably constant. For example, the insulating layer 201 is formed while the substrate 200 is heated at 350° C.

After the insulating layer 201 is formed, heat treatment may be performed thereon under reduced pressure, a nitrogen atmosphere, a rare gas atmosphere, or a nitrogen atmosphere with the ultra-dry air. By the heat treatment, the concentration of hydrogen, moisture, a hydride, a hydroxide, or the like contained in the insulating layer 201 can be reduced. It is preferable that the temperature of the heat treatment be as high as possible among temperatures that the substrate 200 can withstand. Specifically, the heat treatment is preferably performed at a temperature higher than or equal to the temperature in the formation of the insulating layer 201 and lower than the strain point of the substrate 200.

Note that the hydrogen concentration in the insulating layer 201 is preferably lower than 5×10¹⁸ atoms/cm³, further preferably lower than or equal to 1×10¹⁸ atoms/cm³, still further preferably lower than or equal to 5×10¹⁷ atoms/cm³, further more preferably lower than or equal to 1×10¹⁶ atoms/cm³.

After the insulating layer 201 is formed, oxygen doping treatment may be performed on the insulating layer 201 so that the insulating layer 201 includes a region containing oxygen in a proportion higher than that of oxygen in the stoichiometric composition (includes an oxygen-excess region). The “oxygen doping treatment” means that oxygen (which includes at least one of an oxygen radical, an oxygen atom, an oxygen molecule, ozone, an oxygen ion (oxygen molecule ion), and an oxygen cluster ion) is added to a bulk. The term “bulk” is used in order to clarify that oxygen is added not only to a surface of a thin film but also to the inside of the thin film. The “oxygen doping treatment” includes “oxygen plasma doping treatment” in which oxygen which is made to be plasma is added to a bulk. For the oxygen doping treatment, an ion implantation method, an ion doping method, a plasma immersion ion implantation method, plasma treatment performed under an oxygen atmosphere, or the like can be employed. For the ion implantation method, a gas cluster ion beam may be used.

A gas containing oxygen can be used for the oxygen doping treatment. As the gas containing oxygen, oxygen, dinitrogen monoxide, nitrogen dioxide, carbon dioxide, carbon monoxide, or the like can be used. Further, a rare gas may be added to the gas containing oxygen for the oxygen doping treatment.

By introduction of oxygen, a bond between hydrogen and a constituent element of the insulating layer 201 or a bond between the constituent element and a hydroxyl group is cut, and the hydrogen or the hydroxyl group reacts with the oxygen, so that water is produced. Accordingly, heat treatment performed after introduction of oxygen facilitates elimination of hydrogen or the hydroxyl group which is an impurity as water. Therefore, heat treatment may be performed after introduction of oxygen into the insulating layer 201. After that, oxygen may be further introduced into the insulating layer 201 so that the insulating layer 201 is in an oxygen-excess state. The introduction of oxygen and the heat treatment on the insulating layer 201 may be performed alternately a plurality of times. The heat treatment and the introduction of oxygen may be performed at the same time.

Then, a conductive layer containing Cu is formed to a thickness greater than or equal to 100 nm and less than or equal to 500 nm, preferably greater than or equal to 200 nm and less than or equal to 300 nm, over the insulating layer 201 by a sputtering method, a vacuum evaporation method, or a plating method. A resist mask is formed over the conductive layer by a photolithography method, an inkjet method, or the like and the conductive layer is etched using the resist mask; thus, the gate electrode 202, the wiring 212_{—}i, the wiring 203, and the wiring 226 are formed (see FIGS. 11A1 and 11A2 and FIG. 14). Alternatively, the gate electrode 202, the wiring 212_{—}i, the wiring 203, and the wiring 226 can be formed by discharging a conductive nanopaste of copper or the like over the substrate by an inkjet method and baking the conductive nanopaste, without using a resist mask.

For the conductive layer containing Cu, in addition to Cu, a Cu alloy material in which one or more elements of W, Ta, Mo, Ti, Cr, aluminum (Al), zirconium (Zr), calcium (Ca), and the like are added to Cu can be used. By using a Cu alloy material, adhesion of a Cu wiring can be improved or migration such as hillocks can be less likely to occur.

The conductive layer containing Cu may have a single-layer structure or a stacked structure of two or more layers. For example, in order to improve adhesion between the insulating layer 201 and the conductive layer, a two-layer structure may be used in which a layer containing a metal such as W, Ta, Mo, Ti, or Cr, an alloy layer containing any of these in combination, or a layer of a nitride or an oxide of any of these may be formed on the insulating layer 201 and a layer of Cu or a Cu alloy material is formed thereon. Further, a three-layer structure in which the above metal, alloy, nitride, or oxide is stacked over the two-layer structure may be used.

In this embodiment, as the conductive layer containing Cu, a layer in which tantalum nitride and copper are stacked is formed over the insulating layer 201 by a sputtering method. Then, with a resist mask formed through a photolithography process, part of the conductive layer containing Cu is selectively etched, so that the gate electrode 202, the wiring 212_{—}i, the wiring 203, and the wiring 226 are formed. As the etching, a dry etching method or a wet etching method can be used. The conductive layer containing Cu may be etched by both a dry etching method and a wet etching method in combination. For example, Cu may be etched by a wet etching method and tantalum nitride may be etched by a dry etching method.

In the case where the conductive layer is etched by a dry etching method, a gas containing a halogen element can be used as the etching gas. As an example of the gas containing a halogen element, a chlorine-based gas such as chlorine (Cl₂), boron trichloride (BCl₃), silicon tetrachloride (SiCl₄), or carbon tetrachloride (CCl₄)); a fluorine-based gas such as carbon tetrafluoride (CF₄), sulfur hexafluoride (SF₆), nitrogen trifluoride (NF₃), or trifluoromethane (CHF₃)); hydrogen bromide (HBr); or oxygen can be used as appropriate. An inert gas may be added to the etching gas. As a dry etching method, a reactive ion etching (RIE) method can be used.

As a plasma source, a capacitively coupled plasma (CCP), an inductively coupled plasma (ICP), an electron cyclotron resonance (ECR) plasma, a helicon wave plasma (HWP), a microwave-excited surface wave plasma (SWP), or the like can be used. In particular, with ICP, ECR, HWP, and SWP, a high density plasma can be generated. In the case of performing etching by a dry etching method (hereinafter also referred to as “dry etching treatment”), the etching conditions (the amount of electric power applied to a coil-shaped electrode, the amount of electric power applied to an electrode on a substrate side, the temperature of the electrode on the substrate side, and the like) are adjusted as appropriate so that the layer can be etched into a desired shape.

Note that a process in which a resist mask having an appropriate shape is formed over a conductive layer or an insulating layer by a photolithography method is referred to as a photolithography process; in general, after the formation of the resist mask, an etching step and a removal step of the resist mask are performed in many cases. Thus, unless otherwise specified, a photolithography process in this specification includes a step of forming a resist mask, a step of etching a conductive layer or an insulating layer, and a step of removing the resist mask.

Further, the cross-sectional shape of the gate electrode 202, specifically, the cross-sectional shape (e.g., the taper angle or the thickness) of an end portion of the gate electrode 202 is devised, whereby the coverage with the layer formed later can be improved.

Specifically, the end portion of the gate electrode 202 is etched to have a taper shape such that the cross-sectional shape of the gate electrode 202 becomes trapezoidal or triangle. Here, the end portion of the gate electrode 202 has a taper angle θ (see FIG. 11A1) of 80° or less, preferably 60° or less, further preferably 45° or less. Note that the taper angle θ refers to an inclination angle formed by the side surface and bottom surface of the layer having a taper shape when the layer is seen from the direction perpendicular to the cross section of the layer (i.e., the plane perpendicular to the surface of the substrate). A taper angle smaller than 90° is called forward tapered angle and a taper angle of larger than or equal to 90° is called inverse tapered angle.

Alternatively, the cross-sectional shape of the end portion of the gate electrode 202 has a plurality of steps, so that the coverage with the layer formed thereon can be improved. The above is not limited to the gate electrode 202, and by providing a forward taper shape or a step-like shape for a cross section of an end portion of each layer, disconnection of a layer covering the layer (disconnection) can be prevented, so that the coverage becomes good.

Next, the insulating layer 204 and the oxide semiconductor layer 205 are formed over the gate electrode 202, the wiring 212_{—}i, the wiring 203, and the wiring 226 (see FIGS. 11B1 and 11B2 and FIG. 14B).

The insulating layer 204 can be formed by a sputtering method, an MBE method, a CVD method, a pulsed laser deposition method, an ALD method, or the like as appropriate. Alternatively, a high-density plasma CVD method using microwaves or the like can be applied. The insulating layer 204 may be formed using a sputtering apparatus which performs deposition with surfaces of a plurality of substrates set substantially perpendicular to a surface of a sputtering target.

The insulating layer 204 can be formed using a single layer or a stacked layer using one or more of materials selected from silicon oxide, silicon nitride, silicon oxynitride, silicon nitride oxide, aluminum oxide, aluminum nitride, aluminum oxynitride, aluminum nitride oxide, tantalum oxide, gallium oxide, yttrium oxide, lanthanum oxide, hafnium oxide, hafnium silicate, hafnium silicate to which nitrogen is added, and hafnium aluminate to which nitrogen is added.

In this embodiment, as the insulating layer 204, a stack of silicon nitride and silicon oxynitride is formed at a substrate temperature of 200° C. to 350° C. by a high-density plasma CVD method using microwaves. The insulating layer 204 is preferably formed to have a thickness greater than or equal to 50 nm and less than or equal to 800 nm, preferably greater than or equal to 100 nm and less than or equal to 600 nm. The thickness of the insulating layer 204 is preferably formed in consideration of the size of the transistor and the step coverage of the gate electrode 202 with the insulating layer 204.

Generally, a capacitor has such a structure that a dielectric is sandwiched between two electrodes that face to each other, and as the thickness of the dielectric is smaller (as the distance between the two facing electrodes is shorter) or as the dielectric constant of the dielectric is higher, the capacitance becomes higher. However, if the thickness of the dielectric is reduced in order to increase the capacitance of the capacitor, leakage current flowing between the two electrodes tends to increase and the withstand voltage of the capacitor tends to lower.

A portion where a gate electrode, a gate insulating layer, and a semiconductor layer of a transistor overlap with each other functions as the above-described capacitor (hereinafter also referred to as “gate capacitor”). A channel is formed in a region in the semiconductor layer, which overlaps with the gate electrode with the gate insulating layer provided therebetween. In other words, the gate electrode and the channel formation region function as two electrodes of the capacitor, and the gate insulating layer functions as a dielectric of the capacitor. Although it is preferable that the capacitance of the gate capacitor be as high as possible, a reduction in the thickness of the gate insulating layer for the purpose of increasing the capacitance increases the probability of occurrence of an increase in the leakage current or a reduction in the withstand voltage.

In the case where a high-k material such as hafnium silicate (HfSiₓO_{y} (x>0, y>0)), hafnium silicate to which nitrogen is added (HfSiₓO_{y}N_{z} (x>0, y>0, z>0)), hafnium aluminate to which nitrogen is added (HfAlₓO_{y}N_{z} (x>0, y>0, z>0)), hafnium oxide, or yttrium oxide is used for the insulating layer 204, even if the thickness of the insulating layer 204 is made thick, sufficient capacitance between the gate electrode 202 and the oxide semiconductor layer 205 can be ensured.

For example, in the case where a high-k material with a high dielectric constant is used for the insulating layer 204, even if the insulating layer 204 is made thick, a capacitance equivalent to that in the case of using silicon oxide for the insulating layer 204 can be obtained, so that the leakage current between the gate electrode 202 and the oxide semiconductor layer 205 can be reduced. Further, leakage current between the wiring formed of the same layer as the gate electrode 202 and another wiring that overlaps with the wiring can also be reduced. The electrode layer 204 may have a stacked-layer structure of the high-k material and the above-described material.

Further, the insulating layer 204 preferably contains oxygen in a portion which is in contact with the oxide semiconductor layer 205 formed later. The insulating layer 204 in contact with the oxide semiconductor layer 205 preferably contains oxygen which exceeds at least the stoichiometric composition in the film (bulk). For example, in the case where a silicon oxide film is used as the insulating layer 204, the composition formula is SiO_{2+α} (α>0). By using this silicon oxide film as the insulating layer 204, oxygen can be supplied to the oxide semiconductor layer 205, so that favorable characteristics can be obtained.

Further, a portion of the insulating layer 204 which is in contact with the gate electrode 202 formed using the conductive layer containing Cu (including a wiring or an electrode formed using the same layer as the gate electrode) is preferably formed using a material having barrier properties for suppressing Cu diffusion. As the material having barrier properties, for example, silicon nitride or aluminum oxide can be given. By covering the gate electrode 202 with an insulating layer having barrier properties, Cu diffusion can be suppressed. When the insulating layer 201 is formed using a material having barrier properties and the gate electrode 202 is sandwiched between the material having barrier properties, an effect of suppressing Cu diffusion can be improved.

Silicon nitride, aluminum oxide, or the like has barrier properties against oxygen and impurities such as hydrogen, moisture, a hydride, or a hydroxide. By forming the insulating layer 204 with use of the material having barrier properties, not only entry of the above-described impurities from the substrate side but also diffusion of oxygen contained in the insulating layer 204 into the substrate side can be prevented.

In this embodiment, over the gate electrode 202 (including a wiring or an electrode formed using the same layer as the gate electrode), a stack of silicon nitride and silicon oxynitride is formed as the insulating layer 204 by a high-density plasma CVD method using microwaves.

Further, before the insulating layer 204 is formed, an impurity such as moisture or an organic substance which is attached to the surface of a plane on which the layer is formed is preferably removed by plasma treatment using oxygen, dinitrogen monoxide, a rare gas (typically argon), or the like.

After the insulating layer 204 is formed, heat treatment may be performed thereon under reduced pressure, a nitrogen atmosphere, a rare gas atmosphere, or a nitrogen atmosphere with the ultra-dry air. By the heat treatment, the concentration of hydrogen, moisture, a hydride, a hydroxide, or the like contained in the insulating layer 204 can be reduced. It is preferable that the temperature of the heat treatment be as high as possible among temperatures that the substrate 200 can withstand. Specifically, the heat treatment is preferably performed at a temperature higher than or equal to the temperature in the formation of the insulating layer 204 and lower than the strain point of the substrate 200.

Further, after the insulating layer 204 is formed, oxygen doping treatment may be performed on the insulating layer 204 to make the insulating layer 204 an oxygen-excess state. The oxygen doping treatment on the insulating layer 204 is preferably performed after the above-described heat treatment.

The insulating layer 204 containing a large (excessive) amount of oxygen, which serves as an oxygen supply source, is provided so as to be in contact with the oxide semiconductor layer 205, so that oxygen can be supplied from the insulating layer 204 to the oxide semiconductor layer 205 by the heat treatment performed later. By the oxygen supplied to the oxide semiconductor layer 205, oxygen vacancies in the oxide semiconductor layer 205 can be filled.

The insulating layer 204 may be a stack of an insulating layer A and an insulating layer B, the insulating layer A may be formed using a material having barrier properties over the gate electrode 202 (including a wiring or an electrode formed using the same layer as the gate electrode) formed using the conductive layer containing Cu, and the insulating layer B may be formed using a material containing oxygen over the insulating layer A. For example, a silicon nitride film may be formed over the gate electrode 202 as the insulating layer A and a silicon oxynitride film may be formed thereover as the insulating layer B.

Next, an oxide semiconductor layer 215 (not illustrated) to be the oxide semiconductor layer 205 is formed over the insulating layer 204 by a sputtering method.

Planarization treatment may be performed on a region of the insulating layer 204 with which the oxide semiconductor layer 205 is formed in contact before the formation of the oxide semiconductor layer 215. There is no particular limitation on the planarization treatment; polishing treatment (e.g., CMP treatment), dry etching treatment, or plasma treatment can be used.

As the plasma treatment, reverse sputtering in which an argon gas is introduced and plasma is generated can be performed. The reverse sputtering is a method in which voltage is applied to the substrate side with use of an RF power source in an argon atmosphere and plasma is generated in the vicinity of the substrate so that a surface is modified. Instead of an argon atmosphere, a nitrogen atmosphere, a helium atmosphere, an oxygen atmosphere, or the like may be used. With the reverse sputtering, particle substances (also referred to as particles or dust) attached to the surface of the insulating layer 204 can be removed.

Further, as the planarization treatment, polishing treatment, dry etching treatment, or plasma treatment may be performed plural times, or these treatments may be performed in combination. In the case where the treatments are performed in combination, there is no particular limitation on the order of steps and the order can be set as appropriate depending on the roughness of the surface of the insulating layer 204.

A rare gas (typically argon) atmosphere, an oxygen gas atmosphere, or a mixed gas of a rare gas and oxygen is used as appropriate as a sputtering gas used for forming the oxide semiconductor layer 215. It is preferable that a high-purity gas from which impurities such as hydrogen, water, a hydroxyl group, and a hydride are removed be used as the sputtering gas.

The oxide semiconductor layer 215 is preferably formed under a condition that much oxygen is contained (e.g., by a sputtering method in an atmosphere where the proportion of oxygen is 100%) so as to contain much or oversaturated oxygen (preferably include a region containing oxygen in excess of the stoichiometric composition of the oxide semiconductor in a crystalline state).

For example, in the case where an oxide semiconductor layer is formed by a sputtering method, it is preferably performed under conditions where the proportion of oxygen in the sputtering gas is large; it is preferable that the sputtering gas contain an oxygen gas at 100%. The deposition under the conditions where the proportion of oxygen in the sputtering gas is large, in particular, in an atmosphere containing an oxygen gas at 100% enables release of Zn from the oxide semiconductor layer to be suppressed even when the deposition temperature is, for example, higher than or equal to 300° C.

It is preferable that the oxide semiconductor layer 215 be purified so as to contain impurities such as copper, aluminum, and chlorine as little as possible. In a process for manufacturing the transistor, a step which has no risk that such impurities are mixed or attached to the surface of the oxide semiconductor layer is preferably selected as appropriate. Specifically, the copper concentration in the oxide semiconductor layer is less than or equal to 1×10¹⁸ atoms/cm³, preferably less than or equal to 1×10¹⁷ atoms/cm³. In addition, the aluminum concentration in the oxide semiconductor layer is less than or equal to 1×10¹⁸ atoms/cm³. Further, the chlorine concentration in the oxide semiconductor layer is less than or equal to 2×10¹⁸ atoms/cm³.

The concentrations of alkali metals such as sodium (Na), lithium (Li), and potassium (K) in the oxide semiconductor layer 215 are as follows: the concentration of Na is lower than or equal to 5×10¹⁶ cm⁻³, preferably lower than or equal to 1×10¹⁶ cm⁻³, further preferably lower than or equal to 1×10¹⁵ cm⁻³; the concentration of Li is lower than or equal to 5×10¹⁵ cm⁻³, preferably lower than or equal to 1×10¹⁵ cm⁻³; and the concentration of K is lower than or equal to 5×10¹⁵ cm⁻³, preferably lower than or equal to 1×10¹⁵ cm⁻³.

In this embodiment, as the oxide semiconductor layer 215, a 35-nm-thick In—Ga—Zn-based oxide (IGZO) film is formed by a sputtering method using a sputtering apparatus including an AC power supply device. As a target in the sputtering method, a metal oxide target whose composition is In:Ga:Zn=1:1:1 (atomic ratio) is used.

The relative density (the fill rate) of the metal oxide target is greater than or equal to 90% and less than or equal to 100%, preferably greater than or equal to 95% and less than or equal to 99.9%. With the metal oxide target with high relative density, a dense oxide semiconductor layer can be formed.

The oxide semiconductor layer 215 is formed over the insulating layer 204 in such a manner that the substrate 200 is held in a deposition chamber kept under reduced pressure, a sputtering gas from which hydrogen and moisture are removed is introduced into the deposition chamber while moisture remaining therein is removed, and the above target is used. To remove moisture remaining in the deposition chamber, an entrapment vacuum pump such as a cryopump, an ion pump, or a titanium sublimation pump is preferably used. As an exhaustion unit, a turbo molecular pump to which a cold trap is added may be used. A hydrogen atom, a compound containing a hydrogen atom, such as water (H₂O), (preferably a compound containing a carbon atom), or the like is removed from the deposition chamber which is evacuated with the cryopump, whereby the concentration of impurities in the oxide semiconductor layer 215 formed in the deposition chamber can be reduced.

Further, the insulating layer 204 and the oxide semiconductor layer 215 may be formed continuously without exposure to the air. Such continuous formation of the insulating layer 204 and the oxide semiconductor layer 215 without exposure to the air can prevent impurities such as hydrogen and moisture from being attached to a surface of the insulating layer 204.

Next, part of the oxide semiconductor layer 215 is selectively etched by a photolithography process to form the island-shaped oxide semiconductor layer 205 (see FIG. 11B1). A resist mask used for forming the oxide semiconductor layer 205 may be formed by an inkjet method. Formation of the resist mask by an inkjet method needs no photomask; thus, manufacturing cost can be reduced.

Note that the etching of the oxide semiconductor layer 215 may be conducted by a dry etching method, a wet etching method, or both of them. In the case where the oxide semiconductor layer 215 is etched by a wet etching method, a solution obtained by mixing phosphoric acid, acetic acid, and nitric acid, a solution containing oxalic acid, or the like can be used as the etchant. Alternatively, ITO-07N (produced by KANTO CHEMICAL CO., INC.) may be used. In the case where the oxide semiconductor layer 215 is etched by a dry etching method, for example, a dry etching method using a high-density plasma source such as ECR or ICP can be used. As a dry etching method by which uniform electric discharge can be performed over a large area, there is a dry etching method using an enhanced capacitively coupled plasma (ECCP) mode. This dry etching method can be applied even to the case where a substrate of the tenth generation, the size of which exceeds 3 m, is used as the substrate, for example.

Further, heat treatment may be performed in order to remove excess hydrogen (including water or a hydroxyl group) from the oxide semiconductor layer 205 (to perform dehydration or dehydrogenation) after the formation of the oxide semiconductor layer 205. The temperature of the heat treatment is higher than or equal to 300° C. and lower than or equal to 700° C., or lower than the strain point of the substrate. The heat treatment can be performed under reduced pressure, a nitrogen atmosphere, or the like. For example, the substrate may be put in an electric furnace which is a kind of heat treatment apparatus, and the oxide semiconductor layer 205 may be subjected to heat treatment at 450° C. for one hour in a nitrogen atmosphere.

The heat treatment apparatus is not limited to the electric furnace; a device for heating an object by heat conduction or heat radiation from a heating element such as a resistance heating element may be alternatively used. For example, a rapid thermal anneal (RTA) apparatus such as a gas rapid thermal anneal (GRTA) apparatus or a lamp rapid thermal anneal (LRTA) apparatus can be used. The LRTA apparatus is an apparatus for heating an object by radiation of light (an electromagnetic wave) emitted from a lamp such as a halogen lamp, a metal halide lamp, a xenon arc lamp, a carbon arc lamp, a high pressure sodium lamp, or a high pressure mercury lamp. The GRTA apparatus is an apparatus for heat treatment using a high-temperature gas. As the high-temperature gas, an inert gas which does not react with an object to be processed by heat treatment, such as nitrogen or a rare gas like argon, is used.

For example, as the heat treatment, GRTA may be performed as follows; the substrate is put in an inert gas heated at a high temperature of 650° C. to 700° C., is heated for several minutes, and is taken out of the inert gas.

In the heat treatment, it is preferable that water, hydrogen, and the like be contained as less as possible in nitrogen or a rare gas such as helium, neon, or argon. The purity of the nitrogen or the rare gas such as helium, neon, or argon which is introduced into the heat treatment apparatus is set to preferably 6N (99.9999%) or higher, further preferably 7N (99.99999%) or higher (that is, the impurity concentration is preferably 1 ppm or less, further preferably 0.1 ppm or less).

After the oxide semiconductor layer 205 is heated by the heat treatment, a high-purity oxygen gas, a high-purity dinitrogen monoxide gas, or ultra-dry air (air with a moisture amount of less than or equal to 20 ppm (−55° C. by conversion into a dew point), preferably less than or equal to 1 ppm, more preferably less than or equal to 10 ppb according to the measurement with use of a dew point meter of a cavity ring down spectroscopy (CRDS) system) may be introduced into the same furnace. It is preferable that water, hydrogen, or the like be contained as less as possible in the oxygen gas or the dinitrogen monoxide gas. Alternatively, the purity of the oxygen gas or the dinitrogen monoxide gas which is introduced into the heat treatment apparatus is preferably 6N or higher, further preferably 7N or higher (i.e., the impurity concentration in the oxygen gas or the dinitrogen monoxide gas is preferably 1 ppm or less, further preferably 0.1 ppm or less). By the effect of the oxygen gas or the dinitrogen monoxide gas, oxygen which is a main component of the oxide semiconductor and which has been reduced at the same time as the step for removing impurities by dehydration or dehydrogenation is supplied, so that oxygen vacancies in the oxide semiconductor can be reduced, whereby the oxide semiconductor layer 205 can be made an i-type (intrinsic) or substantially i-type oxide semiconductor layer. In this respect, it can be said that an embodiment of the disclosed invention includes a novel technical idea because it is different from an i-type semiconductor such as silicon added with an impurity element.

The timing of performing the heat treatment for dehydration or dehydrogenation is either before or after the island-shaped oxide semiconductor layer 205 is formed as long as it is after formation of the oxide semiconductor layer. The heat treatment for dehydration or dehydrogenation may be performed plural times and may also serve as another heat treatment.

By the dehydration or dehydrogenation treatment, oxygen which is a main component of the oxide semiconductor might be eliminated and thus reduced. There is an oxygen vacancy in a portion where oxygen is eliminated in the oxide semiconductor layer, which causes a donor level which causes a change in the electric characteristics of the transistor owing to the oxygen vacancy.

For the above reason, oxygen doping treatment may be performed on the oxide semiconductor layer 205 after the dehydration or dehydrogenation treatment is performed, so that oxygen can be supplied to the oxide semiconductor layer 205.

Such supply of oxygen by introduction of oxygen into the oxide semiconductor layer 205 after the dehydration or dehydrogenation treatment is performed enables a reduction in oxygen vacancies generated in the oxide semiconductor by the step of removing impurities by the dehydration or dehydrogenation treatment, so that the oxide semiconductor layer 205 can be made i-type (intrinsic). Change in electric characteristics of a transistor including the i-type (intrinsic) oxide semiconductor layer 205 is suppressed, and thus the transistor is electrically stable.

In the case where oxygen is introduced into the oxide semiconductor layer 205, the oxygen doping treatment is performed either directly or through another layer into the oxide semiconductor layer 205.

By the introduction of oxygen, a bond between a constituent element of the oxide semiconductor layer 205 and hydrogen or a bond between the constituent element and a hydroxyl group is cut, and the hydrogen or the hydroxyl group reacts to oxygen, so that water is generated. Therefore, hydrogen or a hydroxyl group, which is an impurity, is more likely to be eliminated in the form of water by performing heat treatment after the oxygen introduction. From the reason above, heat treatment may be performed after oxygen is introduced into the oxide semiconductor layer 205. After that, oxygen may be further introduced into the oxide semiconductor layer 205 so that the oxide semiconductor layer 205 is in an oxygen-excess state. The introduction of oxygen and the heat treatment on the oxide semiconductor layer 205 may be performed alternately a plurality of times. The introduction of oxygen and the heat treatment may be performed at the same time. In order that the oxide semiconductor layer 205 may be supersaturated with oxygen by sufficient supply of oxygen, it is preferable that insulating layers each containing much oxygen (such as silicon oxide layers) be provided so as to surround and be in contact with the oxide semiconductor layer 205.

Here, the hydrogen concentration in the insulating layer containing much oxygen is also important because it affects upon the characteristics of the transistor. In the case where the hydrogen concentration in the insulating layer containing much oxygen is greater than or equal to 7.2×10²⁰ atoms/cm³, variation in initial characteristics of the transistor is increased, L length dependence is increased, and the transistor is significantly degraded by a BT stress test; therefore, the hydrogen concentration in the insulating layer containing much oxygen is preferably less than 7.2×10²⁰ atoms/cm³. That is, it is preferable that the hydrogen concentration in the oxide semiconductor layer be less than or equal to 5×10¹⁹ atoms/cm³ and the hydrogen concentration in the insulating layer containing excess oxygen is less than 7.2×10²⁰ atoms/cm³.

The oxide semiconductor layer 205 may be formed of a stacked layer of a plurality of oxide semiconductor layers. For example, the oxide semiconductor layer 205 may be a stacked layer of a first oxide semiconductor layer and a second oxide semiconductor layer which are formed using metal oxides with different compositions. For example, the first oxide semiconductor layer may be formed using a three-component metal oxide, and the second oxide semiconductor layer may be formed using a two-component metal oxide. Alternatively, for example, both the first oxide semiconductor layer and the second oxide semiconductor layer may be formed using three-component metal oxides.

Further, the constituent elements of the first oxide semiconductor layer and the second oxide semiconductor layer may be the same as each other but the composition of the constituent elements of the first oxide semiconductor layer and the second oxide semiconductor layer may be different from each other. For example, the first oxide semiconductor layer may have an atomic ratio of In:Ga:Zn=1:1:1, and the second oxide semiconductor layer may have an atomic ratio of In:Ga:Zn=3:1:2. Alternatively, the first oxide semiconductor layer may have an atomic ratio of In:Ga:Zn=1:3:2, and the second oxide semiconductor layer may have an atomic ratio of In:Ga:Zn=2:1:3.

At this time, one of the first oxide semiconductor layer and the second oxide semiconductor layer, which is closer to the gate electrode (on a channel side), preferably contains In and Ga at a proportion of In>Ga. The other which is farther from the gate electrode (on a back channel side) preferably contains In and Ga at a proportion of In≦Ga.

In an oxide semiconductor, the s orbital of heavy metal mainly contributes to carrier transfer, and when the In content in the oxide semiconductor is increased, overlap of the s orbitals is likely to be increased. Therefore, an oxide having a composition of In>Ga has higher mobility than an oxide having a composition of In≦Ga. Further, in Ga, the formation energy of an oxygen vacancy is larger and thus an oxygen vacancy is less likely to occur than in In; therefore, the oxide having a composition of In≦Ga has more stable characteristics than the oxide having a composition of In>Ga.

Application of an oxide semiconductor containing In and Ga at a proportion of In>Ga on a channel side, and an oxide semiconductor containing In and Ga at a proportion of In≦Ga on a back channel side allows the mobility and reliability of the transistor to be further improved.

Further, oxide semiconductors whose crystallinities are different from each other may be applied to the first and second oxide semiconductor layers. That is, two of a single crystal oxide semiconductor, a polycrystalline oxide semiconductor, an amorphous oxide semiconductor, and a CAAC-OS may be combined as appropriate. By applying an amorphous oxide semiconductor to at least one of the first oxide semiconductor layer and the second oxide semiconductor layer, internal stress or external stress of the oxide semiconductor layer 205 can be relieved, variation in characteristics of the transistor is reduced, and reliability of the transistor can be further improved.

On the other hand, an amorphous oxide semiconductor is likely to absorb impurities such as hydrogen which generate donors, and is likely to generate oxygen vacancies are likely to be generated, so that the amorphous oxide semiconductor is likely to be made n-type. For this reason, it is preferable to apply an oxide semiconductor having crystallinity such as a CAAC-OS to the oxide semiconductor layer on the channel side.

Further, in a bottom-gate transistor of a channel-etch type, oxygen vacancies are likely to be generated by etching treatment for forming the source electrode and the drain electrode to make the transistor n-type, in the case where an amorphous oxide semiconductor is used on the back channel side. Therefore, in the case of the transistor of a channel-etch type, it is preferable to apply an oxide semiconductor having crystallinity to the oxide semiconductor layer on the back channel side.

Further, the oxide semiconductor layer 205 may have a stacked-layer structure consisting of three or more layers in which an amorphous oxide semiconductor layer is interposed between a plurality of oxide semiconductor layers each having crystallinity. A structure in which an oxide semiconductor layer having crystallinity and an amorphous oxide semiconductor layer are alternately stacked may also be employed.

These two structures used so that the oxide semiconductor layer 205 has a stacked-layer structure including a plurality of layers can be combined as appropriate.

Further, in the case where the oxide semiconductor layer 205 has a stacked structure including a plurality of layers, oxygen doping treatment may be performed each time the oxide semiconductor layer is formed. Such oxygen doping treatment each time the oxide semiconductor layer is formed leads to improvement in the effect of reducing oxygen vacancies in the oxide semiconductor.

Next, part of the insulating layer 204 is selectively removed by a photolithography process, so that the contact hole 218, the contact hole 228 and the contact hole 227 are formed (see FIGS. 10A2 and 10B2, FIG. 11C2, and FIG. 14C). A dry etching method or a wet etching method can be used for the etching of the insulating layer 204. Further, the etching may be performed by a combination of a dry etching method and a wet etching method.

Next, a conductive layer 217 (not illustrated) is formed over the oxide semiconductor layer 205, and part of the conductive layer 217 is selectively etched by a photolithography process, whereby the source electrode 206a and the drain electrode 206b are formed (see FIGS. 11D1 and 11D2 and FIG. 14D).

The conductive layer 217 to be the source electrode 206a and the drain electrode 206b is formed using a material which can withstand heat treatment performed later. For the conductive layer 217, a metal containing an element selected from Al, Cr, Ta, Ti, Mo, and W, a metal nitride containing any of the above elements as a component (e.g., titanium nitride, molybdenum nitride, or tungsten nitride), or the like can be used, for example. A refractory metal film of Ti, Mo, W, or the like or a metal nitride film of any of these elements (a titanium nitride film, a molybdenum nitride film, or a tungsten nitride film) may be stacked either under or on or both of under and on the metal layer of Al or the like. Alternatively, the conductive layer 217 may be formed using a conductive metal oxide. As the conductive metal oxide, indium oxide (In₂O₃), tin oxide (SnO₂), zinc oxide (ZnO), indium oxide-tin oxide (In₂O₃—SnO₂; abbreviated to ITO), indium oxide-zinc oxide (In₂O₃—ZnO), or any of these metal oxide materials in which silicon oxide is contained can be used.

It is preferable that the conductive layer 217 to be the source electrode 206a and the drain electrode 206b do not contain Cu. In particular, it is preferable that the conductive layer 217 do not contain Cu at the main component level (1 wt % or higher). The conductive layer 217 to be the source electrode 206a and the drain electrode 206b is formed in contact with the oxide semiconductor layer 205; therefore, Cu is attached to an exposed surface of the oxide semiconductor layer 205 at the etching of the conductive layer 217, and the attached Cu is diffused into the oxide semiconductor layer 205, which causes degradation of electric characteristics of the transistor and decrease in reliability.

In this embodiment, a stack of W, Al, and Ti is formed as the conductive layer 217 by a sputtering method. The conductive layer 217 can be etched by a wet etching method or a dry etching method. For example, an ICP etching method (dry etching method) can be used under conditions in which the etching gas is BCl₃: Cl₂=750 sccm: 150 sccm, the bias power is 1500 W, the ICP power source is 0 W, and the pressure is 2.0 Pa.

Next, an insulating layer 225 with a thickness of 20 nm to 50 nm which is in contact with part of the oxide semiconductor layer 205 is formed over the source electrode 206a and the drain electrode 206b (see FIGS. 12A1 and 12A2 and FIG. 15A). The insulating layer 225 can be formed using a material and a method similar to those of the insulating layer 201 or the insulating layer 204. For example, a silicon oxide film or a silicon oxynitride film can be formed to be the insulating layer 225 by a sputtering method or a CVD method.

In this embodiment, as the insulating layer 225, a 30-nm-thick silicon oxynitride film is formed by a plasma CVD method. The deposition conditions of the insulating layer 225 may be as follows: the gas flow rate ratio of SiH₄ to N₂O is 20 sccm: 3000 sccm; the pressure is 40 Pa; the RF power supply (power supply output) is 100 W; and the substrate temperature is 350° C.

Next, oxygen 231 is introduced into the insulating layer 225, whereby the insulating layer 225 is made to be the insulating layer 207 which contains excess oxygen (see FIGS. 12B1 and 12B2 and FIG. 15B). At least one of an oxygen radical, ozone, an oxygen atom, and an oxygen ion (including a molecular ion and a cluster ion) is contained in the oxygen 231. The introduction of the oxygen 231 can be performed by oxygen doping treatment.

The introduction of the oxygen 231 may be performed on the entire surface of the insulating layer 225 by plasma treatment at a time, for example, using a linear ion beam. In the case of using the linear ion beam, the substrate 200 or the ion beam is relatively moved (scanned), whereby the oxygen 231 can be introduced into the entire surface of the insulating layer 225.

As a gas for supplying the oxygen 231, a gas containing an oxygen atom may be used; for example, an O₂ gas, an N₂O gas, a CO₂ gas, a CO gas, or an NO₂ gas can be used. A rare gas (e.g., Ar) may be contained in the gas for supplying the oxygen.

Further, in the case where an ion implantation method is used for introducing the oxygen, the dose of the oxygen 231 is preferably greater than or equal to 1×10¹³ ions/cm² and less than or equal to 5×10¹⁶ ions/cm². The content of oxygen in the insulating layer 207 preferably exceeds that of the stoichiometric composition. Such a region containing oxygen in excess of the stoichiometric composition exists in at least part of the insulating layer 207. The depth at which oxygen is implanted may be adjusted as appropriate by implantation conditions.

In this embodiment, the oxygen 231 is introduced by plasma treatment under an oxygen atmosphere. Note that the insulating layer 207 preferably contains impurities such as water or hydrogen as little as possible because it is an insulating layer in contact with the oxide semiconductor layer 205. Therefore, it is preferable to perform heat treatment for removing excess hydrogen (including water or a hydroxyl group) in the insulating layer 225 before the introduction of the oxygen 231. The temperature of the heat treatment for dehydration or dehydrogenation is higher than or equal to 300° C. and lower than or equal to 700° C., or lower than the strain point of the substrate. The heat treatment for dehydration or dehydrogenation can be performed in a manner similar to that of the above-described heat treatment.

The plasma treatment for introducing the oxygen 231 (oxygen plasma treatment) is performed under conditions in which the oxygen flow rate is 250 sccm, the ICP power source is 0 W, the bias power is 4500 W, and the pressure is 15 Pa. Part of oxygen introduced into the insulating layer 225 by the oxygen plasma treatment is introduced into the oxide semiconductor layer 205 through the insulating layer 225. Owing to the introduction of oxygen into the oxide semiconductor layer 205 through the insulating layer 225, plasma damage on the surface of the oxide semiconductor layer 205 can be attenuated, whereby the reliability of the semiconductor device can be improved. It is preferable that the insulating layer 225 be thicker than 10 nm and thinner than 100 nm. If the thickness of the insulating layer 225 be less than or equal to 10 nm, the oxide semiconductor layer 205 is likely to be damaged by the oxygen plasma treatment. On the other hand, if the thickness of the insulating layer 225 be greater than or equal to 100 nm, oxygen introduced by the oxygen plasma treatment might not be supplied sufficiently to the oxide semiconductor layer 205. The heat treatment for dehydration or dehydrogenation of the insulating layer 225 and/or the introduction of the oxygen 231 may be performed plural times. The introduction of oxygen into the insulating layer 225 enables the insulating layer 207 to serve as an oxygen supply layer.

Next, the insulating layer 208 is formed to have a thickness of 200 nm to 500 nm over the insulating layer 207 (see FIGS. 13A1 and 13A2 and FIG. 15C). The insulating layer 208 can be formed using a material and a method similar to those of the insulating layer 201 or the insulating layer 204. For example, a silicon oxide film or a silicon oxynitride film can be formed as the insulating layer 208 by a sputtering method or a CVD method.

In this embodiment, as the insulating layer 208, a 370-nm-thick silicon oxynitride film is formed by a plasma CVD method. The deposition conditions of the insulating layer 208 may be as follows: the gas flow rate ratio of SiH₄ to N₂O is 30 sccm: 4000 sccm; the pressure is 200 Pa; the RF power supply (power supply output) is 150 W; and the substrate temperature is 220° C.

After the formation of the insulating layer 208, heat treatment may be performed thereon under an inert gas atmosphere, an oxygen atmosphere, or an atmosphere of a mixture of an inert gas and oxygen at a temperature higher than or equal to 250° C. and lower than or equal to 650° C., preferably higher than or equal to 300° C. and lower than or equal to 600° C. By this heat treatment, oxygen contained in the insulating layer 207 can be supplied to the oxide semiconductor layer 205, so that oxygen vacancies in the oxide semiconductor layer 205 can be filled. The formation of the insulating layer 208 over the insulating layer 207 enables oxygen included in the insulating layer 207 to be supplied efficiently to the oxide semiconductor layer 205.

Further, oxygen doping treatment may be performed on the insulating layer 208 to introduce the oxygen 231 into the insulating layer 208, whereby the insulating layer 208 is made an oxygen-excess state. The introduction of the oxygen 231 into the insulating layer 208 may be performed in a manner similar to that of the introduction of the oxygen 231 into the insulating layer 207. After the introduction of the oxygen 231 into the insulating layer 208, heat treatment may be performed thereon under an inert gas atmosphere, an oxygen atmosphere, or an atmosphere of a mixture of an inert gas and oxygen at a temperature higher than or equal to 250° C. and lower than or equal to 650° C., preferably higher than or equal to 300° C. and lower than or equal to 600° C.

In a transistor using an oxide semiconductor for its semiconductor layer in which a channel is formed, the interface state density between the oxide semiconductor layer and the insulating layer can be reduced by supplying oxygen into the oxide semiconductor layer. As a result, carrier trapping at the interface between the oxide semiconductor layer and the insulating layer, caused by the operation of the transistor or the like, can be suppressed, and thus, a highly reliable transistor can be obtained.

Further, a carrier may be generated due to oxygen vacancies in the oxide semiconductor layer. In general, oxygen vacancies in the oxide semiconductor layer cause generation of electrons which are carriers in the oxide semiconductor layer. As a result, the threshold voltage of the transistor shifts in the negative direction. By sufficiently supplying oxygen to the oxide semiconductor layer preferably so that the oxide semiconductor layer contains excess oxygen, the density of oxygen vacancies in the oxide semiconductor layer can be reduced.

Next, part of the insulating layer 207 and part of the insulating layer 208 are selectively removed by a photolithography process, so that the contact hole 209, the contact hole 219, the contact hole 229 and the contact hole 227 are formed (see FIGS. 10A2 and 10B2, FIGS. 13B1 and 13B2, and FIG. 14C). A dry etching method or a wet etching method can be used for the etching of the insulating layer 207 and the insulating layer 208. Further, the etching may be performed by a combination of a dry etching method and a wet etching method.

Next, a light-transmitting conductive layer is formed to have a thickness greater than or equal to 30 nm and less than or equal to 200 nm, preferably greater than or equal to 50 nm and less than or equal to 100 nm by a sputtering method, a vacuum evaporation method, or the like, and the pixel electrode 211, the electrode 221, and the electrode 222 are formed by a photolithography process (see FIGS. 10A1, 10A2, 10B1, and 10B2 and FIGS. 13C1 and 13C2).

The light-transmitting conductive layer can be formed using indium oxide, tin oxide, zinc oxide, indium oxide-zinc oxide, ITO, or any of these metal oxide materials containing silicon oxide.

The light-transmitting conductive layer can be formed using a conductive composition containing a conductive high molecule (also referred to as a conductive polymer). The pixel electrode formed using the conductive composition preferably has a sheet resistance of less than or equal to 10000 Ω/square and a light transmittance of greater than or equal to 70% at a wavelength of 550 nm. Further, the resistivity of the conductive high molecule included in the conductive composition is preferably less than or equal to 0.1 Ω·cm.

In this embodiment, an ITO layer with a thickness of 80 nm is formed as the light-transmitting conductive layer. By a photolithography process, the light-transmitting conductive layer is selectively etched; thus, the pixel electrode 211, the electrode 221, and the electrode 222 are formed.

This embodiment can be implemented in appropriate combination with any structure described in the other embodiments.

### Embodiment 2

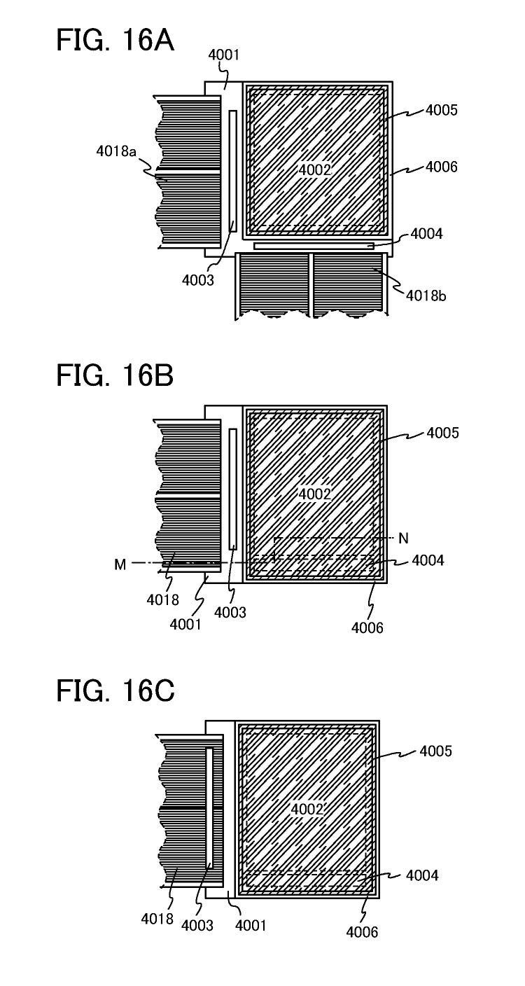

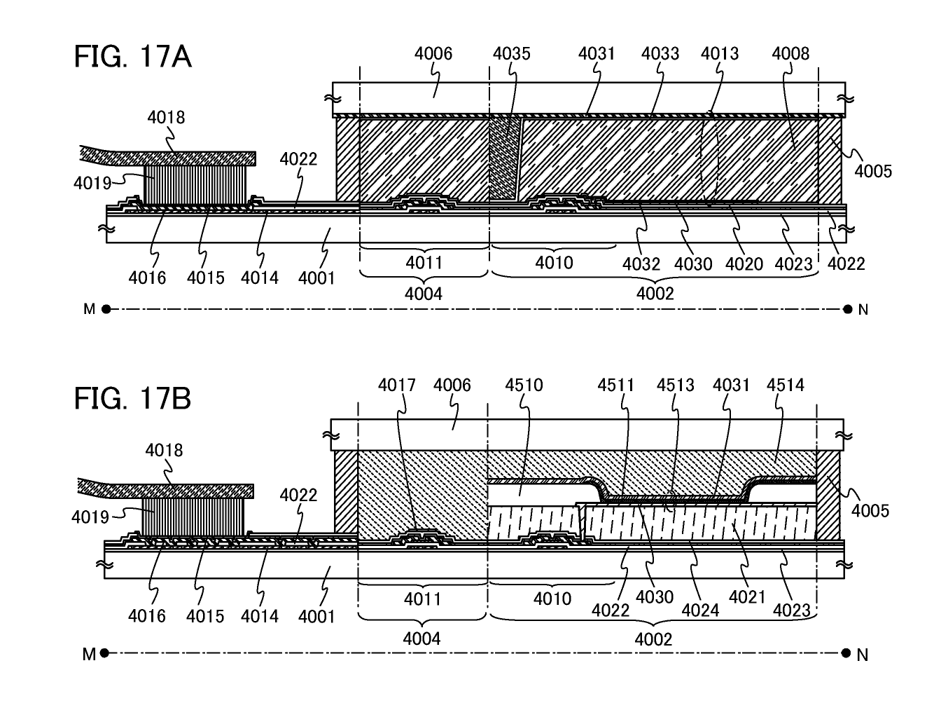

In this embodiment, examples of the display device described in the above embodiment are described with reference to FIGS. 16A to 16C and FIGS. 17A and 17B. Moreover, some or all of driver circuits which include the transistor an example of which is described in the above embodiment can be formed over a substrate where a pixel portion is formed, whereby a system-on-panel can be obtained.

In FIG. 16A, a sealant 4005 is provided to surround a pixel portion 4002 provided over a first substrate 4001, and the pixel portion 4002 is sealed using a second substrate 4006. In FIG. 16A, a signal line driver circuit 4003 and a scan line driver circuit 4004 each are formed using a single-crystal semiconductor or a polycrystalline semiconductor over a substrate prepared separately, and mounted in a region different from the region surrounded by the sealant 4005 over the first substrate 4001. Further, a variety of signals and potentials are supplied to the signal line driver circuit 4003, the scan line driver circuit 4004, and the pixel portion 4002 from flexible printed circuits (FPCs) 4018a and 4018b.

In FIGS. 16B and 16C, the sealant 4005 is provided to surround the pixel portion 4002 and the scan line driver circuit 4004 which are provided over the first substrate 4001. The second substrate 4006 is provided over the pixel portion 4002 and the scan line driver circuit 4004. Consequently, the pixel portion 4002 and the scan line driver circuit 4004 are sealed together with a display element, by the first substrate 4001, the sealant 4005, and the second substrate 4006. In FIGS. 16B and 16C, the signal line driver circuit 4003 which is formed using a single-crystal semiconductor or a polycrystalline semiconductor over a substrate separately prepared is mounted in a region different from the region surrounded by the sealant 4005 over the first substrate 4001. In FIGS. 16B and 16C, a variety of signals and potentials are supplied to the signal line driver circuit 4003, the scan line driver circuit 4004, and the pixel portion 4002 from an FPC 4018.

Although FIGS. 16B and 16C each illustrate the example in which the signal line driver circuit 4003 is formed separately and mounted over the first substrate 4001, embodiments of the present invention are not limited to this structure. The scan line driver circuit may be separately formed and then mounted, or only part of the signal line driver circuit or part of the scan line driver circuit may be separately formed and then mounted.

The connection method of such a separately formed driver circuit is not particularly limited; a chip on glass (COG) method, a wire bonding method, a tape automated bonding (TAB) method, or the like can be used. FIG. 16A illustrates an example in which the signal line driver circuit 4003 and the scan line driver circuit 4004 are mounted by a COG method; FIG. 16B illustrates an example in which the signal line driver circuit 4003 is mounted by a COG method; and FIG. 16C illustrates an example in which the signal line driver circuit 4003 is mounted by a TAB method.

Further, the display device includes in its category, a panel in which the display element is sealed and a module in which an IC or the like including a controller is mounted over the panel.

The display device in this specification means an image display device, a display device, or a light source (including a lighting device). Further, the display device also includes the following modules in its category: a module to which a connector such as an FPC, a TAB tape, or a TCP is attached; a module having a TAB tape or a TCP at the tip of which a printed wiring board is provided; and a module in which an integrated circuit (IC) is directly mounted over the display element by a COG method.

The pixel portion and the scan line driver circuit provided over the first substrate include a plurality of transistors and any of the transistors which are described in the above embodiment can be applied thereto.

As the display element provided in the display device, a liquid crystal element (also referred to as a liquid crystal display element) or a light-emitting element (also referred to as a light-emitting display element) can be used. The light-emitting element includes, in its category, an element whose luminance is controlled by a current or a voltage, and specifically includes, in its category, an inorganic EL element, an organic EL element, and the like. Furthermore, a display medium whose contrast is changed by an electric effect, such as electronic ink, can be used.

FIGS. 17A and 17B are cross-sectional views of a portion taken along chain line M-N in FIG. 16B. As illustrated in FIGS. 17A and 17B, the semiconductor device includes an electrode 4015 and an electrode 4016. The electrode 4015 and the electrode 4016 are electrically connected to a terminal included in the FPC 4018 through an anisotropic conductive layer 4019. The electrode 4016 is electrically connected to a wiring 4014 in an opening formed in an insulating layer 4022.

The electrode 4015 is formed using the same conductive layer as a first electrode layer 4030. The electrode 4016 is formed using the same conductive layer as source and drain electrodes of transistors 4010 and 4011. The wiring 4014 is formed using the same conductive layer as gate electrodes of the transistors 4010 and 4011.

In FIG. 17A, the electrode 4016 and the wiring 4014 are connected to each other in an opening formed in the insulating layer 4022, and in FIG. 17B, the electrode 4016 and the wiring 4014 are connected to each other in a plurality of openings formed in the insulating layer 4022. Since the surface is uneven due to the plurality of openings, the area of contact between the electrode 4015 to be formed later and the anisotropic conductive layer 4019 can be increased. Thus, favorable connection of the FPC 4018 and the electrode 4015 can be obtained.

The pixel portion 4002 and the scan line driver circuit 4004 which are provided over the first substrate 4001 include a plurality of transistors. FIGS. 17A and 17B illustrate the transistor 4010 included in the pixel portion 4002 and the transistor 4011 included in the scan line driver circuit 4004 as an example. In FIG. 17A, an insulating layer 4020 is provided over the transistors 4010 and 4011. In FIG. 17B, a planarization layer 4021 is further provided over an insulating layer 4024. An insulating layer 4023 is an insulating layer serving as a base layer, and the insulating layer 4022 is an insulating layer serving as a gate insulating layer.

In this embodiment, any of the transistors described in the above embodiment can be applied to the transistors 4010 and 4011.

A change in the electric characteristics of any of the transistors described in the above embodiment is suppressed and thus the transistors are electrically stable. Accordingly, a semiconductor device with high reliability can be provided as the semiconductor devices illustrated in FIGS. 17A and 17B.

FIG. 17B illustrates an example in which a conductive layer 4017 is provided over the insulating layer 4024 so as to overlap with a channel formation region of the oxide semiconductor layer of the transistor 4011 for the driver circuit. In this embodiment, the conductive layer 4017 is formed of the same conductive layer as the first electrode layer 4030. The conductive layer 4017 is provided at the position overlapping with the channel formation region of the oxide semiconductor layer, whereby the amount of change in the threshold voltage of the transistor 4011 by a BT test can be further reduced. The potential of the conductive layer 4017 is either the same as or different from that of the gate electrode of the transistor 4011, and the conductive layer 4017 can function as a second gate electrode. The potential of the conductive layer 4017 may be GND, 0 V, or in a floating state. By controlling the potential applied to the conductive layer 4017, the threshold voltage of the transistor can be controlled. Therefore, the conductive layer 4017 is referred to as a back gate electrode in some cases. Note that a back gate electrode may be formed in the transistor 4010.

In addition, the conductive layer 4017 has a function of blocking an external electric field. In other words, the conductive layer 4017 has a function of preventing an external electric field (particularly, a function of preventing static electricity) from affecting the inside (a circuit portion including a thin film transistor). The blocking function of the conductive layer 4017 can prevent a change in electric characteristics of the transistor due to the effect of external electric field such as static electricity.

When the oxide semiconductor layer is covered with the conductive layer 4017, light is prevented from entering the oxide semiconductor layer from the conductive layer 4017 side. Therefore, photodegradation of the oxide semiconductor layer can be prevented and deterioration in electric characteristics such as a shift of the threshold voltage of the transistor can be prevented.

The transistor 4010 included in the pixel portion 4002 is electrically connected to the display element in the display panel. There is no particular limitation on the kind of the display element as long as display can be performed; various kinds of display elements can be employed.

An example of a liquid crystal display device using a liquid crystal element as a display element is illustrated in FIG. 17A. In FIG. 17A, a liquid crystal element 4013 which is a display element includes the first electrode layer 4030, a second electrode layer 4031, and a liquid crystal layer 4008. Insulating layers 4032 and 4033 serving as alignment films are provided so that the liquid crystal layer 4008 is interposed therebetween. The second electrode layer 4031 is provided on the second substrate 4006 side. The second electrode layer 4031 overlaps with the first electrode layer 4030 with the liquid crystal layer 4008 interposed therebetween.

A spacer 4035 is a columnar spacer obtained by selective etching of an insulating layer and is provided in order to control the distance between the first electrode layer 4030 and the second electrode layer 4031 (a cell gap). Alternatively, a spherical spacer may be used.

In the case where a liquid crystal element is used as the display element, a thermotropic liquid crystal, a low-molecular liquid crystal, a high-molecular liquid crystal, a polymer dispersed liquid crystal, a ferroelectric liquid crystal, an anti-ferroelectric liquid crystal, or the like can be used. The above liquid crystal material exhibits a cholesteric phase, a smectic phase, a cubic phase, a chiral nematic phase, an isotropic phase, or the like depending on conditions.

Alternatively, a liquid crystal exhibiting a blue phase for which an alignment film is unnecessary may be used. The blue phase is one of liquid crystal phases, which is generated just before a cholesteric phase changes into an isotropic phase while the temperature of a cholesteric liquid crystal is increased. Since the blue phase appears only in a narrow temperature range, a liquid crystal composition into which a chiral agent is mixed at 5 wt. % or more is used for the liquid crystal layer in order to improve the temperature range. The liquid crystal composition which includes a liquid crystal showing a blue phase and a chiral agent has a short response time of 1 msec or less, has optical isotropy, which makes the alignment process unneeded, and has a small viewing angle dependence. In addition, since an alignment film does not need to be provided and rubbing treatment is unnecessary, electrostatic discharge damage caused by the rubbing treatment can be prevented and defects and damage of the liquid crystal display device can be reduced in the manufacturing process. Thus, productivity of the liquid crystal display device can be increased. A transistor that uses an oxide semiconductor layer particularly has a possibility that electric characteristics of the transistor may change significantly by the influence of static electricity and deviate from the designed range. Therefore, it is more effective to use a liquid crystal material exhibiting a blue phase for the liquid crystal display device including the transistor using an oxide semiconductor layer.

The specific resistivity of the liquid crystal material is greater than or equal to 1×10⁹ Ω·cm, preferably greater than or equal to 1×10¹¹ Ω·cm, further preferably greater than or equal to 1×10¹² Ω·cm. The specific resistance in this specification is measured at 20° C.

In the transistor used in this embodiment, which uses a purified oxide semiconductor layer, the current in an off state (the off-state current) can be made small. Accordingly, an electrical signal such as an image signal can be retained for a long period, and thus a writing interval can be set long in a power-on state. Accordingly, frequency of refresh operation can be reduced, which leads to an effect of suppressing power consumption.

The size of storage capacitor formed in the liquid crystal display device is set considering the leakage current of the transistor provided in the pixel portion or the like so that charge can be held for a predetermined period. The size of the storage capacitor may be set considering the off-state current of the transistor or the like. Owing to the transistor using a high-purity oxide semiconductor layer, it is enough to provide a storage capacitor having a capacitance that is less than or equal to ⅓, preferably less than or equal to ⅕ of the liquid crystal capacitance of each pixel.

In the transistor using the above oxide semiconductor, relatively high field-effect mobility can be obtained, which enables high-speed operation. Consequently, when the above transistor is used in a pixel portion of a semiconductor device having a display function, high-quality images can be displayed. In addition, since a driver circuit portion and a pixel portion can be formed separately over one substrate, the number of components of the semiconductor device can be reduced.

For the liquid crystal display device, a twisted nematic (TN) mode, an in-plane-switching (IPS) mode, a fringe field switching (FFS) mode, an axially symmetric aligned micro-cell (ASM) mode, an optical compensated birefringence (OCB) mode, a ferroelectric liquid crystal (FLC) mode, an antiferroelectric liquid crystal (AFLC) mode, or the like can be used.

A normally black liquid crystal display device such as a transmissive liquid crystal display device utilizing a vertical alignment (VA) mode may also be employed. The vertical alignment mode is a method of controlling alignment of liquid crystal molecules of a liquid crystal display panel, in which liquid crystal molecules are aligned vertically to a panel surface when no voltage is applied. Some examples are given as the vertical alignment mode. For example, a multi-domain vertical alignment (MVA) mode, a patterned vertical alignment (PVA) mode, an advanced super view (ASV) mode, or the like can be used. Moreover, it is possible to use a method called domain multiplication or multi-domain design, in which a pixel is divided into some regions (subpixels) and molecules are aligned in different directions in their respective regions.

In the display device, a black matrix (light-blocking layer), an optical member (optical substrate) such as a polarizing member, a retardation member, or an anti-reflection member, and the like are provided as appropriate. For example, circular polarization may be obtained with a polarizing substrate and a retardation substrate. In addition, a backlight, a side light, or the like may be used as a light source.

As the display method in the pixel portion, a progressive method, an interlace method, or the like can be employed. Further, color elements controlled in the pixel for color display are not limited to three colors: R, G, and B (R, G, and B correspond to red, green, and blue, respectively). For example, R, G, B, and W (W corresponds to white); R, G, B, and one or more of yellow, cyan, magenta, and the like; or the like can be used. Further, the sizes of display regions may be different between respective dots of color elements. The present invention is not limited to a display device for color display but can also be applied to a display device for monochrome display.

Alternatively, as the display element included in the display device, a light-emitting element utilizing electroluminescence can be used. Light-emitting elements utilizing electroluminescence are classified according to whether the light-emitting material is an organic compound or an inorganic compound. In general, the former is referred to as an organic EL element, and the latter is referred to as an inorganic EL element.

In an organic EL element, by application of voltage to a light-emitting element, electrons and holes are separately injected from its pair of electrodes into a layer containing a light-emitting organic compound, and current flows. The carriers (electrons and holes) are recombined, and thus, the light-emitting organic compound is excited; the light-emitting organic compound returns to a ground state from the excited state, thereby emitting light. Owing to such a mechanism, this light-emitting element is referred to as a current-excitation light-emitting element.

Inorganic EL elements are classified according to their element structures into a dispersion-type inorganic EL element and a thin-film inorganic EL element. The dispersion-type inorganic EL element has a light-emitting layer where particles of a light-emitting material are dispersed in a binder, and its light emission mechanism is donor-acceptor recombination type light emission that utilizes a donor level and an acceptor level. The thin-film inorganic EL element has a structure where a light-emitting layer is sandwiched between dielectric layers, which are further sandwiched between electrodes, and its light emission mechanism is localized type light emission that utilizes inner-shell electron transition of metal ions. An example in which the organic EL element is used as the light-emitting element is described here.

To extract light emitted from the light-emitting element, at least one of the pair of electrodes is transparent. The light-emitting element can have a top emission structure in which light emission is extracted through the surface on the side opposite to the substrate; a bottom emission structure in which light emission is extracted through the surface on the substrate side; or a dual emission structure in which light emission is extracted through the surface on the side opposite to the substrate and the surface on the substrate side. A light-emitting element having any of these emission structures can be used.

FIG. 17B illustrates an example of a light-emitting device in which a light-emitting element is used as a display element. A light-emitting element 4513 which is a display element is electrically connected to the transistor 4010 provided in the pixel portion 4002. The structure of the light-emitting element 4513 is not limited to a stacked-layer structure illustrated in FIG. 17B, which includes the first electrode layer 4030, an electroluminescent layer 4511, and the second electrode layer 4031. The structure of the light-emitting element 4513 can be changed as appropriate depending on the direction in which light is extracted from the light-emitting element 4513, or the like.

A partition 4510 can be formed using an organic insulating material or an inorganic insulating material. It is particularly preferable that the partition 4510 be formed using a photosensitive resin material to have an opening over the first electrode layer 4030 so that a sidewall of the opening is formed as a tilted surface with continuous curvature.

The electroluminescent layer 4511 is formed either of a single layer or a plurality of layers stacked.

A protective layer may be formed over the second electrode layer 4031 and the partition 4510 in order to prevent entry of oxygen, hydrogen, moisture, carbon dioxide, or the like into the light-emitting element 4513. As the protective layer, a silicon nitride film, a silicon nitride oxide film, an aluminum oxide film, an aluminum nitride film, an aluminum oxynitride film, an aluminum nitride oxide film, a DLC film, or the like can be formed. In addition, in a space which is formed with the first substrate 4001, the second substrate 4006, and the sealant 4005, a filler 4514 is provided for sealing. It is preferable that a panel be packaged (sealed) with a protective film (such as a laminate film or an ultraviolet curable resin film) or a cover material with high air-tightness and little degasification so that the panel is not exposed to the outside air, in this manner.

As the filler 4514, as well as an inert gas such as nitrogen or argon, an ultraviolet curable resin or a thermosetting resin can be used; polyvinyl chloride (PVC), an acrylic resin, polyimide, an epoxy resin, a silicone resin, polyvinyl butyral (PVB), ethylene vinyl acetate (EVA), or the like can be used. For example, nitrogen is used for the filler.

Further, if needed, an optical film, such as a polarizing plate, a circularly polarizing plate (including an elliptically polarizing plate), a retardation plate (a quarter-wave plate or a half-wave plate), or a color filter, may be provided as appropriate on a light-emitting surface of the light-emitting element. Further, the polarizing plate or the circularly polarizing plate may be provided with an anti-reflection film. For example, anti-glare treatment by which reflected light can be diffused by projections and depressions on the surface so as to reduce the glare can be performed.

The first electrode layer and the second electrode layer (each of which may be called a pixel electrode layer, a common electrode layer, a counter electrode layer, or the like) for applying voltage to the display element may have light-transmitting properties or light-reflecting properties, which depends on the direction in which light is extracted, the position where the electrode layer is provided, and the pattern structure of the electrode layer.

The first electrode layer 4030 and the second electrode layer 4031 can be formed using a light-transmitting conductive material such as indium oxide containing tungsten oxide, indium zinc oxide containing tungsten oxide, indium oxide containing titanium oxide, indium tin oxide containing titanium oxide, indium tin oxide (hereinafter referred to as ITO), indium zinc oxide, or indium tin oxide to which silicon oxide is added.

The first electrode layer 4030 and the second electrode layer 4031 each can be formed using one or more kinds selected from metals such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu), and silver (Ag); alloys thereof; and nitrides thereof.

A conductive composition containing a conductive high molecule (also referred to as a conductive polymer) can also be used for the first electrode layer 4030 and the second electrode layer 4031. As the conductive high molecule, a so-called t-electron conjugated conductive polymer can be used. For example, polyaniline or a derivative thereof, polypyrrole or a derivative thereof, polythiophene or a derivative thereof, a copolymer of two or more kinds of aniline, pyrrole, and thiophene or a derivative thereof can be given.

Since the transistor is easily broken by static electricity or the like, a protection circuit for protecting the driver circuit is preferably provided. The protection circuit is preferably formed using a nonlinear element.

Application of any of the transistors described in the above embodiment enables a highly reliable semiconductor device having a display function to be provided. With the use of any of the wiring structures described in the above embodiment, wiring resistance can be reduced without an increase in width or thickness of the wiring. Thus, a semiconductor device which has high integration, a large size, and a display function with high display quality can be provided. Further, a semiconductor device with low power consumption can be provided.

This embodiment can be implemented in appropriate combination with any structure described in the other embodiments.

### Embodiment 3

In this embodiment, a semiconductor device having an image sensor function for reading data of an object is described as an example of the semiconductor device with reduced wiring resistance which is described in any of the above embodiments.

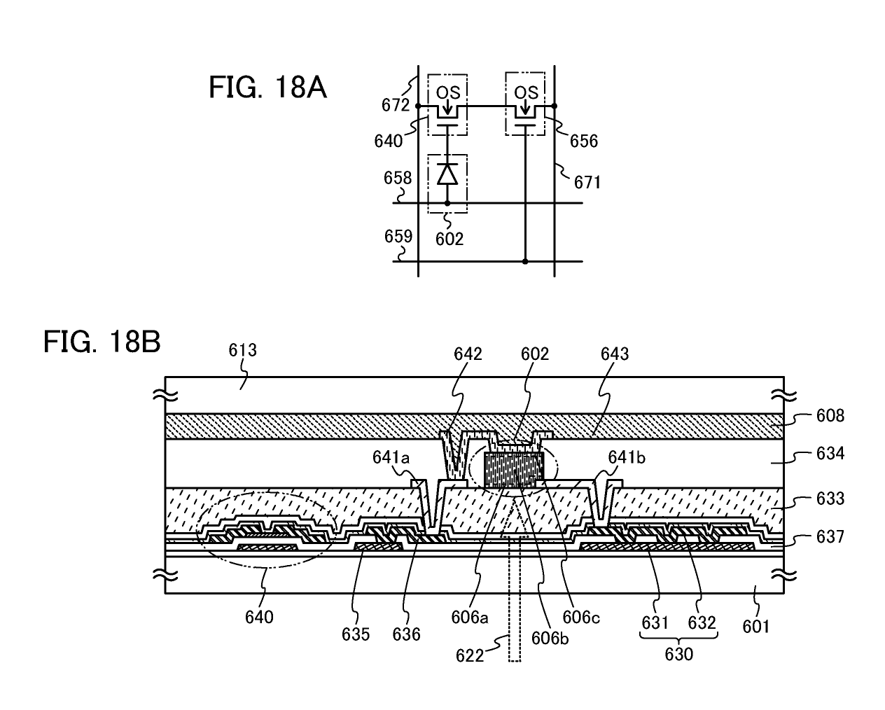

FIG. 18A shows an example of a semiconductor device having an image sensor function. FIG. 18A is an equivalent circuit of a photo sensor and FIG. 18B is a cross-sectional view showing part of the photo sensor.

One electrode of a photodiode 602 is electrically connected to a photodiode reset signal line 658, and the other electrode of the photodiode 602 is electrically connected to a gate of a transistor 640. One of a source and a drain of the transistor 640 is electrically connected to a photo sensor reference signal line 672, and the other of the source and the drain of the transistor 640 is electrically connected to one of a source and a drain of a transistor 656. A gate of the transistor 656 is electrically connected to a gate signal line 659, and the other of the source and the drain of the transistor 656 is electrically connected to a photo sensor output signal line 671.

In the circuit diagram in this specification, a transistor using an oxide semiconductor layer is shown with a symbol “OS” for clear identification as a transistor using an oxide semiconductor layer. In FIG. 18A, the transistor 640 and the transistor 656 are transistors each using an oxide semiconductor for its semiconductor layer where a channel is formed, to which any of the transistors described in the above embodiment can be applied.

FIG. 18B is a cross-sectional view illustrating structure examples of the photodiode 602 and the transistor 640 in the photo sensor. The photodiode 602 functioning as a sensor and the transistor 640 are provided over a substrate 601 having an insulating surface (TFT substrate). A substrate 613 is provided over the photodiode 602 and the transistor 640 with an adhesive layer 608 interposed therebetween.

An insulating layer 633 and an insulating layer 634 are provided over the transistor 640. The photodiode 602 is provided over the insulating layer 633. In the photodiode 602, a first semiconductor layer 606a, a second semiconductor layer 606b, and a third semiconductor layer 606c are sequentially stacked from the insulating layer 633 side between an electrode layer 642 provided over the insulating layer 634 and each of electrodes 641a and 641b formed over the insulating layer 633.

The electrode layer 642 is electrically connected to a conductive layer 636 through the electrode 641a. The conductive layer 636 is electrically connected to the gate electrode of the transistor 640 through the conductive layer 635. Thus, the photodiode 602 is electrically connected to the transistor 640.

Further, the electrode 641b is electrically connected to a wiring 630. The wiring 630 includes a conductive layer 631 containing Cu formed using the same conductive layer as the gate electrode of the transistor 640 and a conductive layer 632 formed using the same conductive layer as the source electrode and the drain electrode of the transistor 640. An insulating layer 637 having barrier properties is formed over the conductive layer 631, the conductive layer 632 is formed over the insulating layer 637, and the conductive layer 631 and conductive layer 632 are electrically connected to each other through a plurality of contact holes formed in the insulating layer 637. When the conductive layer 631 and the conductive layer 632 are electrically connected to each other, wiring resistance of the wiring 630 can be reduced without an increase in the width or thickness of the wiring. Further, by covering the conductive layer 631 containing Cu with the insulating layer 637 having barrier properties, deterioration in electric characteristics or a decrease in reliability of a semiconductor device due to diffusion of Cu can be prevented.

In this embodiment, a pin photodiode in which a semiconductor layer having p-type conductivity as the first semiconductor layer 606a, a high-resistance semiconductor layer (i-type semiconductor layer) as the second semiconductor layer 606b, and a semiconductor layer having n-type conductivity as the third semiconductor layer 606c are stacked is illustrated as an example.

The first semiconductor layer 606a is a p-type semiconductor layer and can be formed using amorphous silicon containing an impurity element imparting p-type conductivity. The first semiconductor layer 606a is formed by a plasma CVD method with use of a semiconductor source gas containing an impurity element belonging to Group 13 (such as boron (B)). As the semiconductor source gas, silane (SiH₄) may be used. Alternatively, Si₂H₆, SiH₂Cl₂, SiHCl₃, SiCl₄, SiF₄, or the like may be used. Further alternatively, an amorphous silicon film which does not contain an impurity element may be formed, and then, an impurity element may be introduced to the amorphous silicon film by a diffusion method or an ion implantation method. Heating or the like may be performed thereon after introducing the impurity element by an ion implantation method or the like in order to diffuse the impurity element. In this case, as the method of forming the amorphous silicon film, an LPCVD method, a vapor deposition method, a sputtering method, or the like may be employed. The first semiconductor layer 606a is preferably formed to have a thickness greater than or equal to 10 nm and less than or equal to 50 nm.

The second semiconductor layer 606b is an i-type semiconductor layer (intrinsic semiconductor layer) and is formed using amorphous silicon. As for formation of the second semiconductor layer 606b, an amorphous silicon film is formed with the use of a semiconductor source gas by a plasma CVD method. As the semiconductor source gas, silane (SiH₄) may be used. Alternatively, Si₂H₆, SiH₂Cl₂, SiHCl₃, SiCl₄, SiF₄, or the like may be used. The second semiconductor layer 606b may be alternatively formed by an LPCVD method, a vapor deposition method, a sputtering method, or the like. The second semiconductor layer 606b is preferably formed to have a thickness greater than or equal to 200 nm and less than or equal to 1000 nm.

The third semiconductor layer 606c is an n-type semiconductor layer and is formed using amorphous silicon containing an impurity element imparting n-type conductivity. The third semiconductor layer 606c is formed by a plasma CVD method with use of a semiconductor source gas containing an impurity element belonging to Group 15 (such as phosphorus (P)). As the semiconductor source gas, silane (SiH₄) may be used. Alternatively, Si₂H₆, SiH₂Cl₂, SiHCl₃, SiCl₄, SiF₄, or the like may be used. Further alternatively, an amorphous silicon film which does not contain an impurity element may be formed, and then, an impurity element may be introduced to the amorphous silicon film by a diffusion method or an ion implantation method. Heating or the like may be performed thereon after introducing the impurity element by an ion implantation method or the like in order to diffuse the impurity element. In this case, as the method of forming the amorphous silicon film, an LPCVD method, a vapor deposition method, a sputtering method, or the like may be employed. The third semiconductor layer 606c is preferably formed to have a thickness greater than or equal to 20 nm and less than or equal to 200 nm.

The first semiconductor layer 606a, the second semiconductor layer 606b, and the third semiconductor layer 606c are not necessarily formed using an amorphous semiconductor; they may be formed using a polycrystalline semiconductor, a microcrystalline semiconductor, or a semi-amorphous semiconductor (SAS).

Further, since the mobility of holes generated by the photoelectric effect is lower than that of electrons, the pin photodiode has better characteristics when the surface on the p-type semiconductor layer side is used as a light-receiving surface. Here, an example where light 622 received by the photodiode 602 from a surface of the substrate 601, over which the pin photodiode is formed, is converted into electric signals is described. Light from the semiconductor layer side having a conductivity type opposite to that of the semiconductor layer side on the light-receiving surface is disturbance light; therefore, the electrode layer is preferably formed from a light-blocking conductive layer. The surface on the n-type semiconductor layer side can alternatively be used as the light-receiving surface.

For reduction of the surface roughness, an insulating layer functioning as a planarization layer is preferably used as each of the insulating layers 633 and 634. The insulating layers 633 and 634 can be formed using, for example, an organic insulating material having heat resistance such as polyimide, an acrylic resin, a benzocyclobutene resin, polyamide, or an epoxy resin. As well as such an organic insulating material, it is possible to use a single layer or a stacked layer of a low-dielectric constant material (a low-k material), a siloxane-based resin, phosphosilicate glass (PSG), borophosphosilicate glass (BPSG), or the like.

With detection of light that enters the photodiode 602, data on an object to be detected can be read. A light source such as a backlight can be used in order to read information on the object.

A change in the electric characteristics of any of the transistors described in the above embodiment is suppressed and thus the transistors are electrically stable. Thus, a highly reliable semiconductor device including the transistor 640 having stable electric characteristics can be provided. Further, the highly reliable semiconductor device can be manufactured at a high yield, whereby high productivity can be achieved. In addition, with any of the wiring structures described in the above embodiment, wiring resistance can be reduced without an increase in the width or thickness of the wiring. Thus, a semiconductor device in which high integration is easily achieved and power consumption is reduced can be provided.

This embodiment can be implemented in appropriate combination with any structure described in the other embodiments.

### Embodiment 4

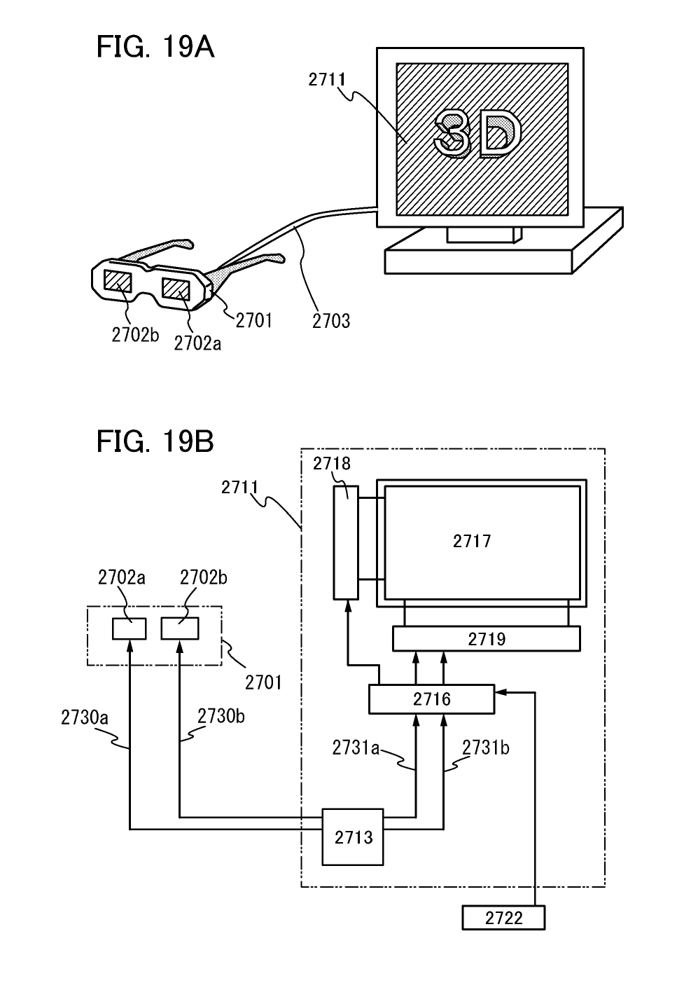

The display devices described in the above embodiments can be applied to semiconductor devices that display a 3D image. In this embodiment, with the use of a display device which switches between an image for a left eye and an image for a right eye at high speed, an example in which a 3D image which is a moving image or a still image is seen with dedicated glasses with which videos of the display device are synchronized is described with reference to FIGS. 19A and 19B.

FIG. 19A illustrates an external view in which a display device 2711 and dedicated glasses 2701 are connected to each other with a cable 2703. Any of the EL display devices disclosed in this specification can be used as the display device 2711. In the dedicated glasses 2701, shutters provided in a panel 2702a for a left eye and a panel 2702b for a right eye are alternately opened and closed, whereby a user can see an image of the display device 2711 as a 3D image.

In addition, FIG. 19B is a block diagram illustrating a main structure of the display device 2711 and the dedicated glasses 2701.

The display device 2711 illustrated in FIG. 19B includes a display control circuit 2716, a display portion 2717, a timing generator 2713, a source line driver circuit 2718, an external operation unit 2722, and a gate line driver circuit 2719. Note that an output signal changes in accordance with operation by the external operation unit 2722 such as a keyboard.

In the timing generator 2713, a start pulse signal and the like are formed, and a signal for synchronizing an image for a left eye and the shutter of the panel 2702a for a left eye, a signal for synchronizing an image for a right eye and the shutter of the panel 2702b for a right eye, and the like are formed.

A synchronization signal 2731a of the image for a left eye is input to the display control circuit 2716, so that the image for a left eye is displayed on the display portion 2717. At the same time, a synchronization signal 2730a for opening the shutter of the panel 2702a for a left eye is input to the panel 2702a for a left eye. In addition, a synchronization signal 2731b of the image for a right eye is input to the display control circuit 2716, so that the image for a right eye is displayed on the display portion 2717. At the same time, a synchronization signal 2730b for opening the shutter of the panel 2702b for a right eye is input to the panel 2702b for a right eye.

Since switching between an image for a left eye and an image for a right eye is performed at high speed, the display device 2711 preferably employs a successive color mixing method (a field sequential method) in which color display is performed by time division with use of light-emitting diodes (LEDs).

Further, since a field sequential method is employed, it is preferable that the timing generator 2713 input signals that synchronize with the synchronization signals 2730a and 2730b to the backlight portion of the light-emitting diodes. Note that the backlight portion includes LEDs of R, G, and B colors.

This embodiment can be implemented in appropriate combination with any of the other embodiments disclosed in this specification.

### Embodiment 5

In this embodiment, examples of electronic devices each including any of the display devices described in the above embodiments are described.

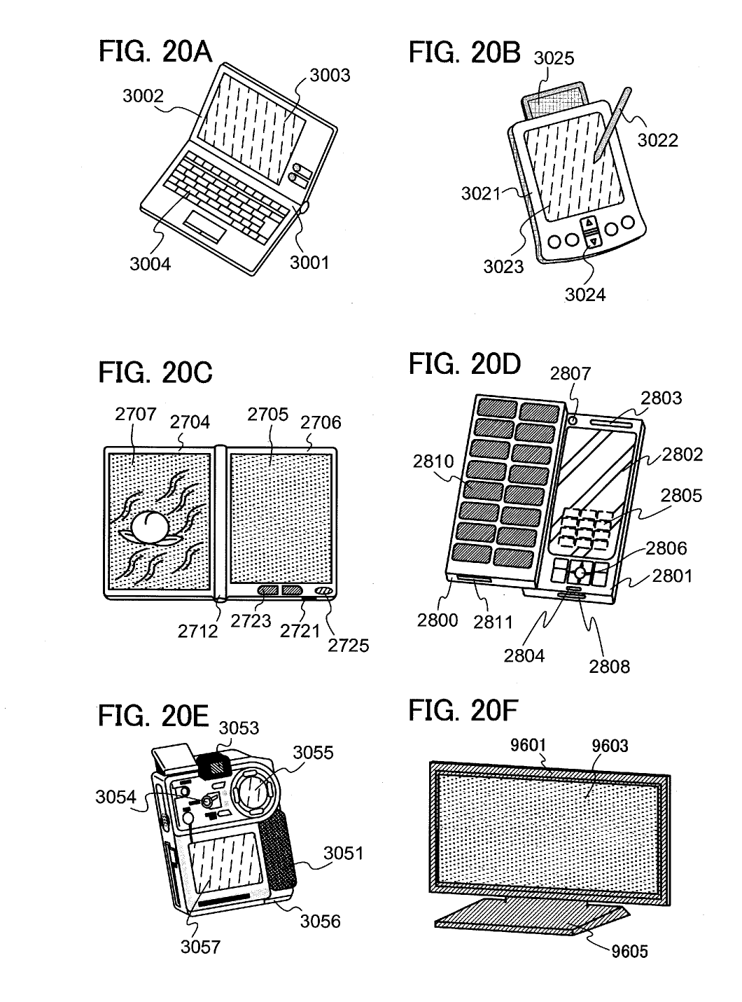

FIG. 20A illustrates a laptop personal computer, which includes a main body 3001, a housing 3002, a display portion 3003, a keyboard 3004, and the like. By using any of the EL display devices described in the above embodiments, a highly reliable laptop personal computer can be obtained.

FIG. 20B is a personal digital assistant (PDA) which includes a main body 3021 provided with a display portion 3023, an external interface 3025, operation buttons 3024, and the like. A stylus 3022 is included as an accessory for operation. By using any of the EL display devices described in the above embodiments, a highly reliable personal digital assistant (PDA) can be obtained.

FIG. 20C illustrates an example of an e-book reader. For example, the e-book reader includes two housings, a housing 2706 and a housing 2704. The housing 2706 is combined with the housing 2704 by a hinge 2712, so that the e-book reader can be opened and closed using the hinge 2712 as an axis. With such a structure, the e-book reader can operate like a paper book.

A display portion 2705 and a display portion 2707 are incorporated in the housing 2706 and the housing 2704, respectively. The display portion 2705 and the display portion 2707 may display a continuous image or different images. In the structure where different images are displayed on different display portions, for example, the right display portion (the display portion 2705 in FIG. 20C) displays text and the left display portion (the display portion 2707 in FIG. 20C) displays graphics. By using any of the EL display devices described in the above embodiments, a highly reliable e-book reader can be obtained.

FIG. 20C illustrates an example in which the housing 2706 is provided with an operation portion and the like. For example, the housing 2706 is provided with a power supply terminal 2721, operation keys 2723, a speaker 2725, and the like. With the operation keys 2723, pages can be turned. Note that a keyboard, a pointing device, or the like may also be provided on the surface of the housing, on which the display portion is provided. Furthermore, an external connection terminal (an earphone terminal, a USB terminal, or the like), a recording medium insertion portion, and the like may be provided on the back surface or the side surface of the housing. Further, the e-book reader may have a function of an electronic dictionary.

The e-book reader may transmit and receive data wirelessly. Through wireless communication, desired book data or the like can be purchased and downloaded from an e-book server.

FIG. 20D illustrates a mobile phone, which includes two housings, a housing 2800 and a housing 2801. The housing 2801 includes a display panel 2802, a speaker 2803, a microphone 2804, a pointing device 2806, a camera lens 2807, an external connection terminal 2808, and the like. In addition, the housing 2800 includes a solar cell 2810 having a function of charge of the mobile phone, an external memory slot 2811, and the like. Further, an antenna is incorporated in the housing 2801.

The display panel 2802 is provided with a touch screen. A plurality of operation keys 2805 which is displayed as images is illustrated by dashed lines in FIG. 20D. Note that a boosting circuit by which a voltage output from the solar cell 2810 is increased to be sufficiently high for each circuit is also included.

In the display panel 2802, the display direction can be appropriately changed depending on a usage pattern. Further, the mobile phone is provided with the camera lens 2807 on the same surface as the display panel 2802, and thus it can be used as a video phone. The speaker 2803 and the microphone 2804 can be used for videophone calls, recording and playing sound, and the like as well as voice calls. Moreover, the housings 2800 and 2801 in a state where they are developed as illustrated in FIG. 20D can shift by sliding so that one is lapped over the other; therefore, the size of the mobile phone can be reduced, which makes the mobile phone suitable for being carried.

The external connection terminal 2808 can be connected to an AC adapter and various types of cables such as a USB cable, and charging and data communication with a personal computer or the like are possible. Moreover, a large amount of data can be stored by inserting a storage medium into the external memory slot 2811 and can be moved.

Further, in addition to the above functions, an infrared communication function, a television reception function, or the like may be provided. By using any of the EL display devices described in the above embodiments, a highly reliable mobile phone can be provided.

FIG. 20E illustrates a digital video camera which includes a main body 3051, a display portion A 3057, an eyepiece 3053, an operation switch 3054, a display portion B 3055, a battery 3056, and the like. By using any of the EL display devices described in the above embodiments, a highly reliable digital video camera can be provided.

FIG. 20F illustrates an example of a television set. In the television set, a display portion 9603 is incorporated in a housing 9601. The display portion 9603 can display images. Here, the housing 9601 is supported by a stand 9605. By using any of the EL display devices described in the above embodiments, a highly reliable television set can be provided.

The television set can be operated by an operation switch of the housing 9601 or a separate remote controller. Further, the remote controller may be provided with a display portion for displaying data output from the remote controller.

Note that the television set is provided with a receiver, a modem, and the like. With the use of the receiver, general television broadcasting can be received. Moreover, when the television set is connected to a communication network with or without wires via the modem, one-way (from a sender to a receiver) or two-way (between a sender and a receiver or between receivers) information communication can be performed.

This embodiment can be implemented in appropriate combination with any of the structures described in the other embodiments.

This application is based on Japanese Patent Application serial no. 2012-057974 filed with Japan Patent Office on Mar. 14, 2012, the entire contents of which are hereby incorporated by reference.

What is claimed is:

1. A semiconductor device comprising:
a first wiring comprising copper;
an insulating layer over the first wiring, the insulating layer comprising a contact hole;
a second wiring over the insulating layer; and
an oxide semiconductor layer over the insulating layer,
wherein the second wiring is electrically connected to the first wiring through the contact hole.

2. The semiconductor device according to claim 1, further comprising:
a gate electrode comprising copper,
wherein the gate electrode and the first wiring are over and in contact with a same layer, and
wherein the oxide semiconductor layer overlaps with the gate electrode with the insulating layer therebetween.

3. The semiconductor device according to claim 1, further comprising:
an electrode over the insulating layer, the electrode being in contact with the oxide semiconductor layer,
wherein the electrode is in contact with the insulating layer, and
wherein the second wiring is in contact with the insulating layer.

4. The semiconductor device according to claim 1, wherein the second wiring overlaps with the first wiring.

5. The semiconductor device according to claim 1, wherein the first wiring comprises a first layer comprising copper and a second layer comprising a metal element having a higher melting point than copper.

6. The semiconductor device according to claim 1, wherein the first wiring comprises a first layer comprising copper and a second layer comprising a nitride of a metal element having a higher melting point than copper.

7. The semiconductor device according to claim 1, wherein the insulating layer comprises silicon nitride or aluminum oxide.

8. A semiconductor device comprising:
a first wiring comprising copper;
a second wiring comprising copper;
an insulating layer over the first wiring and the second wiring, the insulating layer comprising a first contact hole, a second contact hole, and a third contact hole;
a third wiring over the insulating layer; and
an oxide semiconductor layer over the insulating layer,
wherein the third wiring is electrically connected to the first wiring through the first contact hole,
wherein the third wiring is electrically connected to the first wiring through the second contact hole, and
wherein the third wiring is electrically connected to the second wiring through the third contact hole.

9. The semiconductor device according to claim 8, further comprising:
a gate electrode comprising copper,
wherein the gate electrode, the first wiring, and the second wiring are over and in contact with a same layer, and
wherein the oxide semiconductor layer overlaps with the gate electrode with the insulating layer therebetween.

10. The semiconductor device according to claim 8, further comprising:
an electrode over the insulating layer, the electrode being in contact with the oxide semiconductor layer,
wherein the electrode is in contact with the insulating layer, and
wherein the third wiring is in contact with the insulating layer.

11. The semiconductor device according to claim 8, wherein the third wiring overlaps with the first wiring and the second wiring.

12. The semiconductor device according to claim 8, wherein each of the first wiring and the second wiring comprises a first layer comprising copper and a second layer comprising a metal element having a higher melting point than copper.

13. The semiconductor device according to claim 8, wherein each of the first wiring and the second wiring comprises a first layer comprising copper and a second layer comprising a nitride of a metal element having a higher melting point than copper.

14. The semiconductor device according to claim 8, wherein the insulating layer comprises silicon nitride or aluminum oxide.

15. A semiconductor device comprising:
a first wiring comprising copper;
an insulating layer over the first wiring, the insulating layer comprising a first contact hole and a second contact hole;
a second wiring over the insulating layer;
a third wiring over the insulating layer; and
an oxide semiconductor layer over the insulating layer,
wherein the second wiring is electrically connected to the first wiring through the first contact hole, and
wherein the third wiring is electrically connected to the first wiring through the second contact hole.

16. The semiconductor device according to claim 15, further comprising:
a gate electrode comprising copper,
wherein the gate electrode and the first wiring are over and in contact with a same layer, and
wherein the oxide semiconductor layer overlaps with the gate electrode with the insulating layer therebetween.

17. The semiconductor device according to claim 15, further comprising:
an electrode over the insulating layer, the electrode being in contact with the oxide semiconductor layer,
wherein the electrode is in contact with the insulating layer,
wherein the second wiring is in contact with the insulating layer, and
wherein the third wiring is in contact with the insulating layer.

18. The semiconductor device according to claim 15, wherein the first wiring comprises a first layer comprising copper and a second layer comprising a metal element having a higher melting point than copper.

19. The semiconductor device according to claim 15, wherein the first wiring comprises a first layer comprising copper and a second layer comprising a nitride of a metal element having a higher melting point than copper.

20. The semiconductor device according to claim 15, wherein the insulating layer comprises silicon nitride or aluminum oxide.
